(19) United States
(12) Patent Application Publication
(10) Pub. No.: US 2003/0048625 A1
(43) Pub. Date: Mar. 13, 2003

(54) Mounting structure, mounting method and mounting apparatus for high frequency circuit components

(76) Inventors: Tsuguhisa Ishii, Kobe-shi (JP); Ritsu Katsuoka, Kobe-shi (JP); Sinji Sakamoto, Kobe-shi (JP); Yukio Tooyama, Kobe-shi (JP); Yasunari Hara, Kobe-shi (JP)

Correspondence Address: Fogg and Associates, LLC, P.O. Box 581339, Minneapolis, MN, 55458-1339, US

(21) Appl. No.: 10/173,142

(22) Filed: Jun. 17, 2002

(30) Foreign Application Priority Data
Jun. 18, 2001 (JP) 2001-183926
May 10, 2002 (JP) 2002-135901

(51) Int. Cl. H05K 9/00

(52) U.S. Cl. 361/818

(57) ABSTRACT

By mounting electronic circuit components using a microstrip line, transmission loss and variation in performance are reduced. At least one projection of substantially uniform height is provided on each of four side surfaces of the components. The components are disposed on the chassis by bringing their projections into contact with adjacent circuit components. A heat-resistant film or a heat-resistant tape is adhered to one or both side surfaces of adjacent side surfaces of the components, to dispose the components in contact with each other. A component-mounting nozzle is used to adsorb the components, and position them on the chassis in contact with a guide fitted on the chassis or in the vicinity of the chassis. It is also possible to position the components with actuators located around the chassis, after the components are provisionally disposed on the chassis with the component-mounting nozzle.

### BACKGROUND OF THE INVENTION

1. Field of the Invention

The present invention relates to a mounting structure, a mounting method, and a mounting apparatus for high frequency circuit components such as modules. The invention particularly relates to a mounting structure, a mounting method, and a mounting apparatus for mounting high frequency circuit components to be used for a radar apparatus or the like, without transmission loss and by reducing the variation in the performance.

2. Description of the Related Art

In recent years, radar apparatuses as automatic tracing apparatuses have been employed in not only airplanes but also in vehicles that run on the ground. Each radar apparatus is provided with a high frequency circuit that applies a base band signal of a transmission triangular wave to a voltage control oscillator, to transmit a signal from a transmission antenna after carrying out a frequency modulation, and receive a signal reflected from a target object. This high frequency circuit branches a high frequency signal obtained from the transmission voltage control oscillator to apply a part of this signal to a receiving mixer that is supplied with a reception signal of the receiving antenna. With this arrangement, it is possible to obtain a beat signal corresponding to a distance from the target and a relative speed, thereby to measure the distance to the target and the relative speed. The high frequency circuit that is used in the radar apparatus handles a weak signal. Therefore, it is essential that the high frequency circuit has no transmission loss and no variation in its performance.

In constructing a high frequency circuit by combining a plurality of high frequency circuit components, the components are usually mounted on absolute coordinates. Therefore, there occurs a variation in the intervals between circuit components (modules having components mounted on the substrate in the present example), due to the component tolerance and variance in the mounting positions.

For example, in mounting electronic circuit components that constitute a high frequency circuit on a chassis, these components are mounted by setting center coordinates of each electronic circuit component based on a standard point. As there is variance in the external shapes of electronic circuit components due to component tolerance, there has been a problem that the intervals between the electronic circuit components are different. Further, as the coordinates are set by taking into account the external shape tolerance of the components and the mounting variance of the mounting apparatuses, there has been a problem of the occurrence of gaps between the electronic circuit components.

At the time of connecting between the high frequency circuit components, in order to avoid changes in the line impedance, there have been used gold ribbon lines or the like having the same width as that of the high frequency pattern of the electronic circuit components. The gold ribbon lines provide a loop to respond to stress that is generated due to changes in temperature. As a high frequency signal is attenuated at a connection section between the electronic circuit components, it is ideal that the electronic circuit components that constitute a high frequency circuit are linear and have substantially zero gaps in the line that propagates waves.

However, in the propagation of a high frequency wave using a microstrip line, a variation in the intervals between the electronic circuit components becomes the cause of mismatching of line impedance. This leads to variation in the transmission loss, which results in the occurrence of variation in performance between finished products.

Further, at the time of connecting electronic circuit components to form a high frequency circuit, when the gold ribbon lines or the like having a loop are used to respond to the stress that is generated due to changes in temperature, this has become the cause of mismatching of the line impedance. This has resulted in the occurrence of transmission loss.

Further, when the component-mounting facility currently available is used to make the gap between the electronic circuit components substantially zero, there has been the following problem. It has not been possible to obtain mounting precision to realize an ideal propagation line, unless sub-micron order is pursued for the mechanical repetition precision of systems that constitute the component-mounting facility, such as an image recognition system, an electronic circuit component and sub-straight positioning system, and an X-Y-Z axis moving system.

When the mechanical repetition precision of the systems that constitute the component-mounting facility is set to a sub-micron order, the facility becomes very expensive and has low productivity. On the other hand, when the repetition precision of the facility is sacrificed, gaps occur between the mounted electronic circuit components. As a result, the electric characteristic of the high frequency circuit is degraded.

### SUMMARY OF THE INVENTION

In mounting electronic circuit components to structure a high frequency circuit using a microstrip line, it is therefore an object of the present invention to provide a mounting structure, a mounting method, and mounting apparatus for a high frequency circuit, capable of reducing transmission loss and variation in performance, without making expensive the systems that constitute a component-mounting apparatus.

According to a structure of mounting a plurality of high frequency circuit components on a chassis relating to the present invention, each high frequency circuit component has at least one projection of substantially the same height provided on each of the four side surfaces, and the high frequency circuit components are disposed by bringing their projections into contact with adjacent circuit components respectively.

Further, a heat-resistant film or a heat-resistant tape is adhered to one or both side surfaces of mutually adjacent side surfaces of the high frequency circuit components, thereby to dispose the adjacent circuit components in contact with each other. With this arrangement, it is possible to keep a constant interval between the circuit components.

According to the mounting structure of the high frequency circuit components relating to the present invention, the structure has at least three high frequency circuit components, with their side surfaces brought into contact with each other, and has a plurality of contacted positions.

Further, the high frequency circuit components are ranked within size tolerance of circuit components, and circuit components of the same rank are used for the mounting. Further, the high frequency circuit components have their length and width ranked into S, M, and L sizes, respectively, and are classified into a plurality of ranks based on a combination of the length and the width.

According to the mounting structure of the high frequency circuit components relating to the present invention, the structure has a plurality of blocks each including a plurality of, preferably at least three, high frequency circuit components, with the side surfaces of the high frequency circuit components within each block brought into contact with each other, and has a plurality of contacted positions, and the blocks are disposed with an interval of an external shape tolerance between adjacent blocks.

Further, the blocks are divided into transmission system blocks and receiving system blocks.

According to the mounting structure of the high frequency circuit components relating to the present invention, the structure has a plurality of blocks each including a plurality of, preferably at least three, high frequency circuit components, with the side surfaces of the high frequency circuit components within each block brought into contact with each other, and has a plurality of contacted positions, and the blocks are disposed with a closest distance between the adjacent blocks substantially zero.

According to the mounting structure of the high frequency circuit components relating to the present invention, the circuit components are fixed to the chassis with a conductive adhesive agent. Further, end surfaces of the circuit components at which the circuit components are brought into contact with each other are ground beforehand.

Further, the circuit components are fixed to the chassis with an anisotropic conductive sheet.

Further, the coefficient of linear expansion of the circuit components is set substantially the same as the coefficient of linear expansion of the chassis.

Further, the high frequency circuit components are connected to each other with a gold ribbon not having a loop. Further, the coefficient of linear expansion of the circuit components is set substantially the same as the coefficient of linear expansion of the chassis.

According to the mounting structure of the high frequency circuit components relating to the present invention, the high frequency circuit components are connected to each other with solder or a conductive adhesive agent.

Further, the high frequency circuit components are connected to each other with a metal plate, and the metal plate is connected to the circuit components with an anisotropic conductive sheet or by welding.

Further, the high frequency circuit components are connected to each other with a gold ribbon, and the gold ribbon is connected to the circuit components with a conductive adhesive agent, or an anisotropic conductive sheet, or by welding.

According to the structure of mounting the high frequency circuit components on a chassis relating to the present invention, a reference end surface is provided on the chassis, and a reference surface to fix the high frequency circuit components on the chassis is provided. A base section of a tool having the base section and a claw section is brought into contact with the reference end surface of the chassis, and the circuit components are fixed to the chassis using the end surface of the claw section of the contacted tool as a reference surface.

Further, a stage is provided on the reference end surface of the chassis. The base section of the tool is brought into contact with a bottom section and a side section of this stage. The circuit components are fixed to the chassis using the end surface of the claw section of the contacted tool as a reference.

The reference end surface of the chassis is provided in the X axis direction and the Y axis direction of the chassis.

According to the structure of mounting the high frequency circuit components on a chassis relating to the present invention, a recess section is provided on the chassis. The high frequency circuit components are fixed to the chassis using the side surface of the corner of the provided recess section as a reference.

Further, the high frequency circuit components are fixed to the chassis using a projection provided on the chassis as a reference.

Further, a hole is provided in the chassis. The high frequency circuit components are fixed to the chassis using a projection of a tool inserted into the hole as a reference.

Further, an antenna-connecting hole provided on a chassis is used as a reference for fixing the high frequency circuit components onto the chassis.

As a method of mounting a plurality of high frequency circuit components onto a chassis, it is possible to employ the following methods.

(1) A method of positioning high frequency circuit components onto a chassis, by adsorbing each high frequency circuit component with a component-mounting nozzle, conveying each high frequency circuit component onto the chassis or onto a guide fitted to the vicinity of the chassis with the component-mounting nozzle, and bringing at least one of the four side surfaces of the high frequency circuit component into contact with the guide.

According to this method, when there is already a high frequency circuit component that has been positioned on the chassis by bringing the high frequency circuit component into contact with the guide, a high frequency circuit component to be positioned next is applied to this high frequency circuit component that has already been positioned. With this arrangement, it is possible to position the next high frequency circuit component by making the already-positioned high frequency circuit component play the role of a guide.

Further, according to this method, it is possible to convey the high frequency circuit components using a plurality of the same number of component-mounting nozzles as the number of the components. Further, after sequentially adsorbing the high frequency circuit components with the plurality of component-mounting nozzles, it is possible to position the high frequency circuit components while the high frequency circuit components are kept adsorbed with the plurality of component-mounting nozzles. After finishing the positioning of the high frequency circuit components, it is possible to collectively convey the high frequency circuit components onto the chassis and mount them on the chassis with the plurality of component-mounting nozzles.

(2) A method of positioning high frequency circuit components onto a chassis, by adsorbing each high frequency circuit component with a component-mounting nozzle, conveying each high frequency circuit component onto the chassis to provisionally mount the high frequency circuit component, and adjusting the position of the high frequency circuit component on the chassis with an actuator disposed around the chassis.

According to this method, it is possible to provisionally dispose a plurality of high frequency circuit components on a sub-stage in advance, and collectively convey the plurality of provisionally disposed high frequency circuit components onto the chassis by adsorbing the high frequency circuit components with one or a plurality of component-mounting nozzles.

(3) A method of collectively positioning high frequency circuit components onto a chassis, by adsorbing each high frequency circuit component with a component-mounting nozzle, conveying each high frequency-circuit component onto a sub-stage with the component-mounting nozzle in advance, adjusting the position of the high frequency circuit component by bringing the high frequency circuit component into contact with a guide provided on the sub-stage, and collectively conveying the plurality of high frequency circuit components after the positional adjustment from the sub-stage onto the chassis by collectively adsorbing the high frequency circuit components with the component-mounting nozzle.

(4) A method of collectively positioning high frequency circuit components onto a chassis, by adsorbing each high frequency circuit component with a component-mounting nozzle, conveying each high frequency circuit component onto a sub-stage with the component-mounting nozzle in advance, adjusting the position of the high frequency circuit component on the sub-stage with an actuator disposed around the sub-stage, and collectively conveying the plurality of high frequency circuit components after the positional adjustment from the sub-stage onto the chassis by collectively adsorbing the high frequency circuit components with the component-mounting nozzle.

In the above collective positioning methods (3) and (4), it is possible to convey the high frequency circuit components using a plurality of the same number of component-mounting nozzles as the number of the components.

(5) A method of mounting high frequency circuit components when a high frequency circuit constructed of a plurality of high frequency circuit components has a plurality of systems, wherein the high frequency circuit components are positioned on a chassis, by provisionally disposing the plurality of high frequency circuit components on a sub-stage for each component that belongs to each system in advance, conveying the plurality of high frequency circuit components provisionally disposed for each system onto the chassis by collectively adsorbing the high frequency circuit components with a component-mounting nozzle, and adjusting the positions of the high frequency circuit components for each system on the chassis. The positional adjustment of the high frequency circuit components for each system on the chassis is carried out with a guide that is fitted to the chassis.

(6) A method of mounting high frequency circuit components when a high frequency circuit constructed of a plurality of high frequency circuit components has a plurality of systems, wherein the high frequency circuit components are positioned on a chassis, by provisionally disposing the plurality of high frequency circuit components on a sub-stage for each component that belongs to each system in advance, conveying the plurality of high frequency circuit components provisionally disposed for each system onto the chassis by collectively adsorbing the high frequency circuit components with a component-mounting nozzle, and adjusting the positions of the high frequency circuit components for each system on the chassis. The positional adjustment of the high frequency circuit components for each system on the chassis is carried out with actuators that are provided in the vicinity of the chassis.

(7) A method of mounting high frequency circuit components when a high frequency circuit constructed of a plurality of high frequency circuit components has a plurality of systems, wherein the high frequency circuit components are collectively positioned on a chassis, by adsorbing the plurality of high frequency circuit components for each component that belongs to each system with a component-mounting nozzle, conveying the high frequency circuit components that belong to each system onto a sub-stage with the component-mounting nozzle, positioning the components for each system on the sub-system, collectively adsorbing the positioned components of each system from the sub-system with the component-mounting nozzle, and collectively conveying the high frequency circuit components onto the chassis. The positional adjustment of the high frequency circuit components for each system on the sub-stage is carried out with a guide that is fitted to the sub-stage.

(8) A method of mounting high frequency circuit components when a high frequency circuit constructed of a plurality of high frequency circuit components has a plurality of systems, wherein the high frequency circuit components are collectively positioned on a chassis, by adsorbing the plurality of high frequency circuit components for each component that belongs to each system with a component-mounting nozzle, conveying the high frequency circuit components that belong to each system onto a sub-stage with the component-mounting nozzle, positioning the components for each system on the sub-system, collectively adsorbing the positioned components of each system from the sub-system with the component-mounting nozzle, and collectively conveying the high frequency circuit components onto the chassis. The positional adjustment of the high frequency circuit components for each system on the sub-stage is carried out with actuators that are provided in the vicinity of the sub-stage.

A mounting apparatus of a first mode that mounts a plurality of high frequency circuit components onto a chassis according to the present invention is constructed of at least the following members:

(A) a mounting stage on which a chassis is fitted that is mounted with the high frequency circuit components,

(B) at least one component-mounting nozzle that can adsorb each high frequency circuit component,

(C) a vacuum supplying unit that supplies negative pressure to the component-mounting nozzle,

(D) a component-mounting nozzle moving unit that moves the component-mounting nozzle from a position where the high frequency circuit components are located to the mounting stage,

(E) an X-Y stage for moving the mounting stage, and

(F) a positioning mechanism for positioning the high frequency circuit components on the chassis.

A mounting apparatus in a second mode that mounts a plurality of high frequency circuit components onto a chassis according to the present invention is constructed of at least the following members:

(a) a mounting stage on which a chassis is fitted that is mounted with the high frequency circuit components,

(b) at least one component-mounting nozzle that can adsorb each high frequency circuit component,

(c) a vacuum supplying unit that supplies negative pressure to the component-mounting nozzle,

(d) a component-mounting nozzle moving unit that moves the component-mounting nozzle from the position of the high frequency circuit components,

(e) a sub-stage on which the high frequency circuit components are mounted temporarily,

(f) an X-Y stage for moving the sub-stage or the mounting stage, and

(g) a positioning mechanism for positioning the high frequency circuit components on either the sub-stage or the chassis.

A positioning mechanism for positioning on the chassis may be a guide or an actuator. When the high frequency circuit components are to be positioned with the actuator, it is possible to move the high frequency circuit components with the actuator while detecting circuit patterns on the high frequency circuit components with a pattern positioning apparatus. It is also possible to use a microscope or the like for this pattern positioning apparatus.

Further, in all the mounting apparatuses of the present invention, it is possible to further provide pressing pins to press the high frequency circuit components against the chassis in a pressing state. By individually pressing a high frequency circuit component positioning of which on the chassis has been completed, it is possible to fix the high frequency circuit component onto the chassis by pressing the high frequency circuit component against an adhesive agent that has been coated on the chassis.

According to the mounting structure of high frequency circuit components relating to the present invention, it is possible to make constant the intervals between the circuit components that are mounted on a chassis in predetermined small intervals. Therefore, it is possible to avoid variation in the transmission loss and a variation in the performance. Further, according to the mounting method and the mounting apparatus for high frequency circuit components relating to the present invention, it is possible to mount the high frequency circuit components on the chassis without gaps at least between the circuits of the same system. Therefore, since the circuit components are closely adhered to each other, transmission loss and variation in the performance are minimized. Further, according to the mounting method and the mounting apparatus for high frequency circuit components relating to the present invention, it is possible to mount a large number of high frequency circuit components even if the number of the circuit components is large. In this way, it is possible to minimize transmission loss and avoid variation in performance.

### BRIEF DESCRIPTION OF THE DRAWINGS

The present invention will be more clearly understood from the description as set forth below with reference to the accompanying drawings, of which:

FIG. 1A is a view showing a layout of circuit components on a chassis according to a conventional mounting structure of high frequency circuit components.

FIG. 1B is an enlarged view of FIG. 1A according to a conventional mounting structure of high frequency circuit components.

FIG. 2 is a view for explaining a problem of a conventional mounting structure of high frequency circuit components.

FIG. 3 is a cross-sectional view showing a mounting structure of high frequency circuit components according to a first embodiment of the present invention.

FIG. 4 is a top plan view showing a structure of circuit components in the first embodiment of a mounting structure of high frequency circuit components according to the present invention.

FIG. 5A is a cross-sectional view showing another structure of circuit components in the first embodiment of a mounting structure of high frequency circuit components according to the present invention.

FIG. 5B is a perspective view showing one example of a structure of a heat-resistant film or a heat-resistant tape shown in FIG. 5A.

FIG. 5C is a perspective view showing another example of a structure of a heat-resistant film or a heat-resistant tape shown in FIG. 5A.

FIG. 6 is a cross-sectional view showing a structure of circuit components in a second embodiment of a mounting structure of high frequency circuit components according to the present invention.

FIG. 7A is a view showing a conventional mounting structure of high frequency circuit components.

FIG. 7B is a view showing a mounting structure of high frequency circuit components in the second embodiment of the present invention.

FIG. 8 is a view for explaining a problem when high frequency circuit components are mounted by simply bringing the side surfaces of the components into contact with each other.

FIG. 9 is a view showing an example of a mounting structure of high frequency circuit components according to the present invention when there are two systems, one of a transmission system and one of a receiving system in a high frequency circuit.

FIG. 10 is a view showing an example of a mounting structure of high frequency circuit components according to the present invention when there are two systems, one of a system A and one of a system B in a high frequency circuit.

FIG. 11A is a top plan view for explaining a reference tool and a reference end surface to determine a reference in a third embodiment of a mounting structure according to the present invention.

FIG. 11B is a top plan view showing a state wherein a reference tool has been fitted to the reference end surface shown in FIG. 11A.

FIG. 12A is a side view for explaining a reference tool and a reference end surface to determine a reference in the third embodiment of a mounting structure according to the present invention.

FIG. 12B is a side view showing a state wherein a reference tool has been fitted to the reference end surface shown in FIG. 12A.

FIG. 13A is a cross-sectional view of a chassis showing still another example to determine a reference in the third embodiment of a mounting structure according to the present invention.

FIG. 13B is a top plan view showing a state wherein circuit components have been mounted on the chassis shown in FIG. 13A.

FIG. 14 is a top plan view showing still another example to determine a reference in the third embodiment of a mounting structure according to the present invention.

FIG. 15 is a view showing still another example to determine a reference in the third embodiment of a mounting structure according to the present invention.

FIG. 16A is a view showing a chassis and a reference tool to determine a reference in a mounting structure according to the present invention when an antenna is used as an input and output unit of a high frequency circuit.

FIG. 16B is a view showing a state wherein one circuit component has been mounted on the chassis by fitting a reference tool on the chassis shown in FIG. 16A.

FIG. 16C is an assemble perspective view showing fitting positions of a chassis and circuit components.

FIG. 17 is a view showing a structure of fixing circuit components onto a chassis in a fourth embodiment of a mounting structure according to the present invention.

FIG. 18A to FIG. 18C are views for explaining a problem of fixing circuit components onto a chassis in the fourth embodiment of a mounting structure according to the present invention.

FIG. 19 is a view showing a structure in which circuit components and a chassis prepared using materials of substantially the same coefficient of linear expansion are fixed together in a fifth embodiment of a mounting structure according to the present invention.

FIG. 20 is a view showing a structure in which the circuit components are connected together with a gold ribbon having no loop in the fifth embodiment of a mounting structure according to the present invention.

FIG. 21 is a view showing a state wherein the circuit components and a chassis are prepared using materials of substantially the same coefficient of linear expansion in the structure shown in FIG. 19.

FIG. 22 is a view showing a structure in which the circuit components are connected to each other with solder in a sixth embodiment of a mounting structure according to the present invention.

FIG. 23 is a view showing a structure in which the circuit components are connected to each other with a metal plate in the sixth embodiment of a mounting structure according to the present invention.

FIG. 24 is a view showing another structure in which the circuit components are connected to each other with a metal plate in the sixth embodiment of a mounting structure according to the present invention.

FIG. 25A is an assembly perspective view showing a structure of a chassis and a guide that are used in a first method of mounting high frequency circuit components according to the present invention.

FIG. 25B is a perspective view showing a state after assembling the chassis and the guide shown in FIG. 25A.

FIG. 26A to FIG. 26C are views for explaining stages of mounting high frequency circuit components in the first method of mounting high frequency circuit components according to the present invention.

FIG. 27 is a view showing a modification of the first method of mounting high frequency circuit components according to the present invention.

FIG. 28 is a view showing another modification of the first method of mounting high frequency circuit components according to the present invention.

FIG. 29A to FIG. 29C are views for explaining stages of mounting high frequency circuit components in a second method of mounting high frequency circuit components according to the present invention.

FIG. 30A to FIG. 30C are views for explaining stages of mounting high frequency circuit components as a first modification of the second method of mounting high frequency circuit components according to the present invention.

FIG. 31 is a view for explaining a second modification of the second method of mounting high frequency circuit components according to the present invention.

FIG. 32A to FIG. 32C are views for explaining stages of mounting high frequency circuit components in a third method of mounting high frequency circuit components according to the present invention.

FIG. 33A to FIG. 33C are views for explaining stages of mounting high frequency circuit components in a fourth method of mounting high frequency circuit components according to the present invention.

FIG. 34A to FIG. 34D are views for explaining stages of mounting high frequency circuit components in a fifth method of mounting high frequency circuit components according to the present invention.

FIG. 35A to FIG. 35D are views for explaining stages of mounting high frequency circuit components in a sixth method of mounting high frequency circuit components according to the present invention.

FIG. 36A to FIG. 36D are views for explaining stages of mounting high frequency circuit components in a seventh method of mounting high frequency circuit components according to the present invention.

FIG. 37A to FIG. 37H are views for explaining stages of mounting high frequency circuit components in an eighth method and a ninth method of mounting high frequency circuit components according to the present invention.

FIG. 38A is a side view of a mounting apparatus for high frequency circuit components in a first mode of a first structure according to the present invention.

FIG. 38B is a top plan view of the mounting apparatus shown in FIG. 38A.

FIG. 39A is a side view of the mounting apparatus for high frequency circuit components in a second mode of the first structure according to the present invention.

FIG. 39B is a top plan view of the mounting apparatus shown in FIG. 39A.

FIG. 40A is a side view showing an outline of a second structure of a mounting apparatus for high frequency circuit components according to the present invention.

FIG. 40B is a top plan view of the mounting apparatus shown in FIG. 40A.

FIG. 41A is a cross-sectional view showing a process of coating an adhesive agent onto a chassis.

FIG. 41B is top plan view showing a state wherein a nozzle that has adsorbed a second component has descended toward a chassis at the time of mounting high frequency circuit components.

FIG. 41C is a cross-sectional side view of the chassis shown in FIG. 41B.

FIG. 42A is a top plan view showing a state wherein circuit components have been brought into contact with an actuator with a nozzle in the state shown in FIG. 41B.

FIG. 42B is a side cross-sectional view of the chassis shown in FIG. 42A.

FIG. 43A is a top plan view for explaining a patterning after mounting the components onto a chassis.

FIG. 43B is a side cross-sectional view of the chassis shown in FIG. 43A.

FIG. 43C is a side cross-sectional view for explaining the pressing of the components against the chassis with pressing pins after the patterning.

### DESCRIPTION OF THE PREFERRED EMBODIMENTS

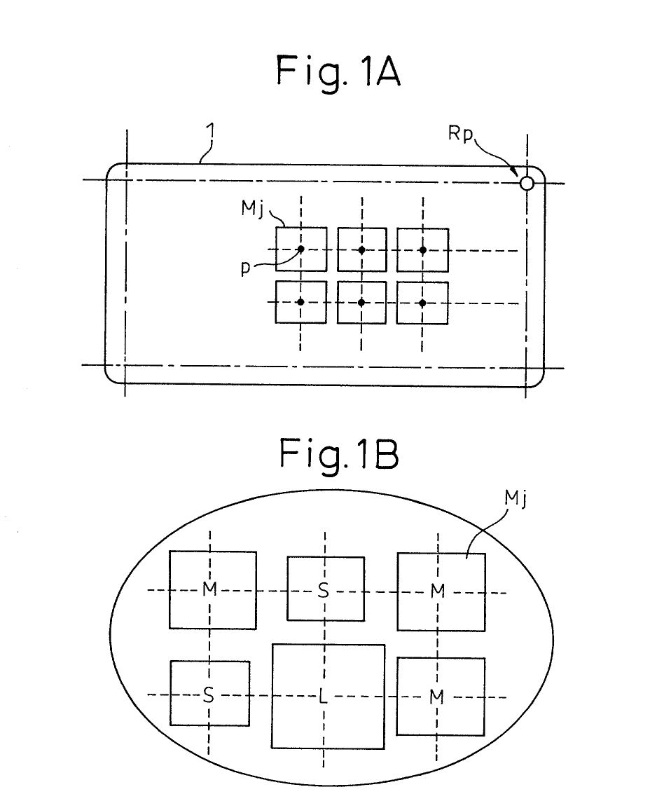

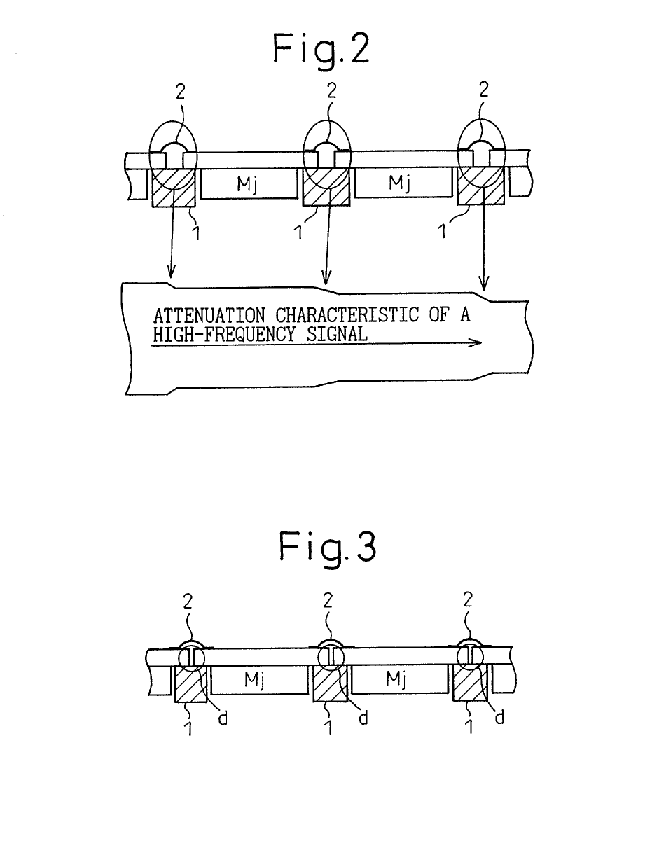

Before describing the preferred embodiments, an explanation will be given of the conventional mounting structure of high frequency circuit components shown in FIGS. 1A to 2.

FIGS. 1A and 1B are views showing examples of a conventional mounting structure of high frequency circuit components. As shown in FIG. 1A, in mounting electronic circuit components that constitute a high frequency circuit on a chassis 1, the high frequency circuit components are mounted after setting coordinates of a center point p for each high frequency circuit component Mj, based on a reference point Rp. In this case, as shown in FIG. 1B, there is variance in the external shapes of these high frequency circuit components Mj due to the component tolerance, and consequently, the intervals between the high frequency circuit components are different. Further, as the coordinates are set by taking into account the external shape tolerance of the components and the mounting variance of the mounting apparatuses, gaps occur between the electronic circuit components.

At the time of connecting between the high frequency circuit components, in order to avoid changes in the line impedance, there have been used gold ribbon lines 2 or the like having the same width as that of the high frequency pattern of the electronic circuit components Mj as shown in FIG. 2. The gold ribbon lines provide a loop to respond to stress that is generated due to changes in temperature. A reference number 1 denotes a chassis. As shown in the lower side of FIG. 2, a high frequency signal is attenuated at a connection section between the electronic circuit components. Therefore, the electronic circuit components that constitute a high frequency circuit are ideally linear and have substantially zero gaps in the line that propagates waves.

However, in the propagation of a high frequency wave using a microstrip line, variation in the intervals between the electronic circuit components as shown in FIG. 1A becomes the cause of mismatching of line impedance. This leads to variation in the transmission loss, which results in a variation in performance between finished products. Further, at the time of connecting electronic circuit components to form a high frequency circuit, when the gold ribbon lines or the like having a loop are used to respond to the stress that is generated due to changes in temperature, this has become the cause of mismatching of the line impedance. This has resulted in the occurrence of transmission loss. Further, when the component-mounting facility currently available is used to make the gaps between the electronic circuit components substantially zero, there has been the following problem. It has not been possible to obtain mounting precision to realize an ideal propagation line, unless an expensive facility which can detect a sub-micron order of length is used for the mechanical repetition precision of systems that constitute the component-mounting facility, such as an image recognition system, an electronic circuit component and sub-straight positioning system, and an X-Y-Z axis moving system.

In mounting electronic circuit components to structure a high frequency circuit using a microstrip line, it is therefore an object of the present invention to provide a mounting structure, a mounting method, and a mounting apparatus for a high frequency circuit, capable of reducing transmission loss and variation in performance, without making expensive the systems that constitute a component-mounting apparatus. Preferred embodiments of the present invention will be explained in detail below with reference to the drawings.

[First Embodiment]

There will be explained a first embodiment of the present invention that minimizes a variation in the transmission loss and a variation in the performance, by reducing a variation in the intervals between the mounted circuit components. In the embodiment explained below, the circuit components are rectangular or regular square shape when observed from the top. However, the circuit components to which the present invention can be applied are not limited to these shapes.

FIG. 3 shows a mounting structure of high frequency circuit components according to the first embodiment of the present invention. In this structure, an interval d between adjacent circuit components of a plurality of circuit components Mj to be mounted on a chassis 1 is made constant to avoid variation. The structure which ensures that this interval d is constant will be explained below.

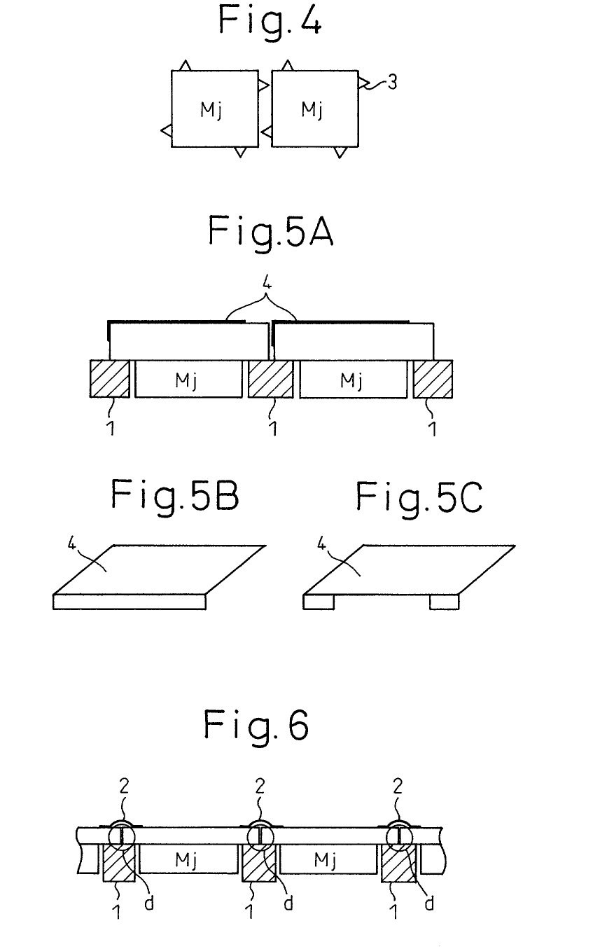

FIG. 4 shows one example of a structure for ensuring that the interval between the circuit components Mj is constant. In this example, each high frequency circuit component Mj has at least one projection 3 of the same height provided on each of the four side surfaces. The projections 3 are provided at positions where they are not brought into contact with each other when the circuit components Mj are connected adjacently. At the time of mounting the circuit components Mj, the projections 3 are brought into contact with the adjacent circuit components Mj. As the projections 3 are also provided on the adjacent circuit components Mj, the intervals between the adjacent circuit components Mj become equal to the height of the projections 3, and are thus constant. The height of these projections 3 is 50 μm, for example.

FIG. 5A to FIG. 5C show other examples of a structure for ensuring that the interval between the circuit components Mj is constant. In these examples, a heat-resistant film or a heat-resistant tape 4 is provisionally fixed to a surface of each of the adjacent circuit components Mj. The heat-resistant film or the heat-resistant tape 4 has a structure as shown in FIG. 5B or FIG. 5C, and this film or tape is adhered to each circuit component Mj at the time of mounting the circuit component Mj. After the circuit components Mj have been mounted, the heat-resistant films or heat-resistant tapes 4 are removed. As shown in FIG. 5A, the heat-resistant film or the heat-resistant tape 4 is positioned on only one side surface of each of the adjacent circuit components Mj, at the time of mounting the circuit components Mj. However, it is also possible to provide the heat-resistant film or the heat-resistant tape 4 on both side surfaces of the adjacent circuit components Mj.

[Second Embodiment]

A mounting structure that reduces transmission loss by minimizing the interval between the circuit components Mj will be explained next, with reference to FIG. 6. In this example, a circuit component Mj to be mounted next is brought directly into contact with the circuit component Mj that has been mounted previously, thereby to bring both side surfaces into contact with each other. Based on this mounting method, the interval d between the adjacent circuit components Mj is minimum. As a result, the transmission loss is reduced, and the influence on the line impedance is minimized.

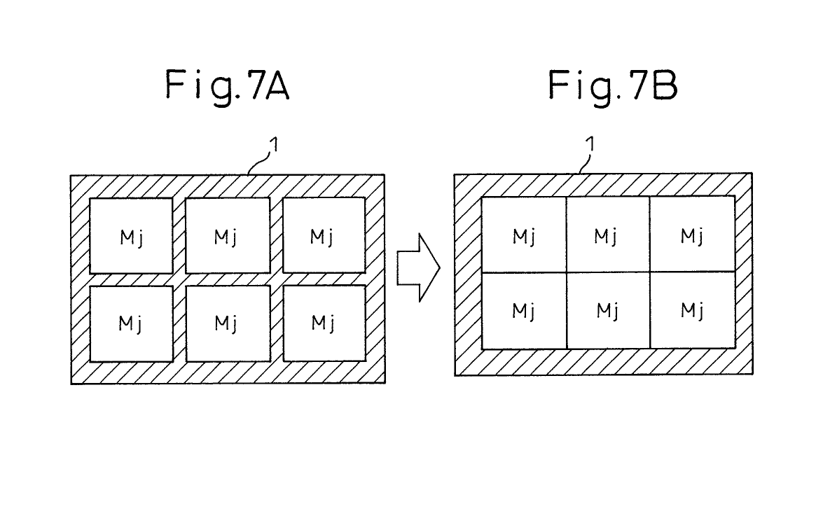

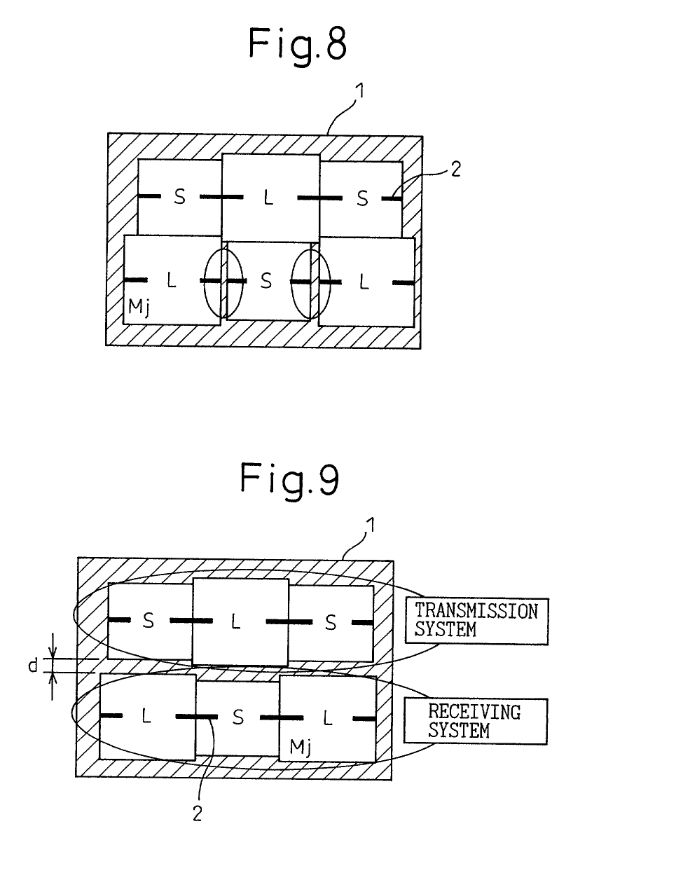

FIG. 7A and FIG. 7B show a comparison between the conventional mounting structure and the mounting structure of the second embodiment. In the conventional mounting structure shown in FIG. 7A, there are gaps between adjacent circuit components Mj. However, in the mounting structure of the second embodiment shown in FIG. 7B, there are substantially no gaps between the adjacent circuit components Mj, and consequently there is substantially no transmission loss.

It is preferable that the sizes of all the circuit components Mj be the same. However, the circuit components Mj have external size tolerance. Assume that a circuit component Mj having a large external size has a length L, and a circuit component Mj having a small external size has a length S. When the sizes of the adjacent circuit components Mj are different, attempts to mount the circuit components Mj by bringing their side surfaces into contact with each other will result in a gap between the adjacent circuit components Mj.

According to the second embodiment of the present invention, even when the circuit components Mj have external size tolerance, when there are a plurality of available signal transmission routes, it is possible to minimize variation both in transmission loss and performance by reducing variation in the intervals between adjacent circuit components Mj. According to the present invention, when there are a plurality of available signal transmission routes, the circuit components Mj are divided into blocks of a plurality of systems. When the circuit components Mj are mounted on each block by bringing the side surfaces of the circuit components Mj directly into contact with each other, it is possible to minimize the intervals and avoid transmission loss.

Assume that a high frequency circuit has two transmission routes made of a transmission system and a receiving system, respectively, like the radar apparatus, for example. In this case, as shown in FIG. 9, a plurality of circuit components Mj having different lengths due to the external size tolerance are divided into the transmission system and the receiving system, in order to ensure that one is not easily influenced by the other. The circuit components Mj of each block are mounted by bringing their side surfaces into contact with each other, thereby to minimize intervals between the side surfaces. When the sizes of the blocks are different, the side surfaces of the circuit components Mj are not brought into contact with each other, and these circuit components are mounted as they are at predetermined intervals.

In the example shown in FIG. 9, the sizes of the circuit components Mj of the transmission system are S, L and S, and the sizes of the circuit components Mj of the receiving system are L, S and L. When the sizes of the circuit components Mj are in the above combination, the circuit components Mj of the transmission system are laid out adjacently along the direction of flow of a signal, and are mounted by bringing their side surfaces into contact with each other, thereby to minimize the intervals therebetween. Next, in a similar manner, the circuit components Mj of the receiving system are laid out adjacently along the direction of flow of a signal, and are mounted by bringing their side surfaces into contact with each other, thereby to minimize the intervals therebetween. The transmission system and the receiving system are disposed with an interval ‘d’, of the tolerance of the circuit components Mj between the systems.

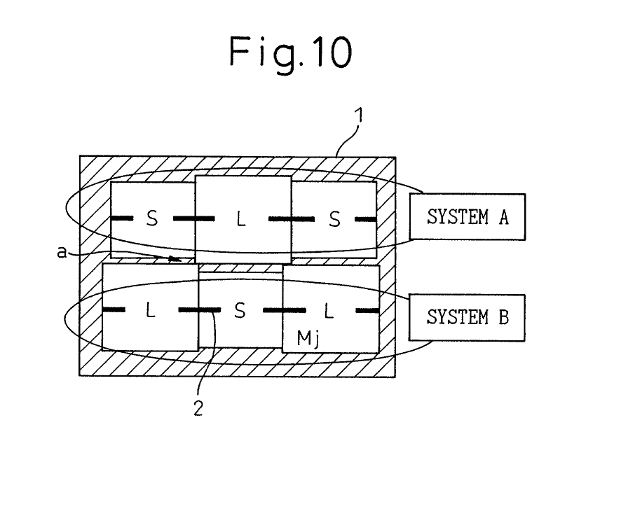

FIG. 10 shows another example in which circuit components Mj having different sizes due to the external size tolerance are laid out by dividing the circuit components Mj into two systems, A and B. In this example, the side surfaces of the circuit components Mj are brought into contact with each other for the system A and for the system B respectively, thereby to minimize the intervals between the adjacent circuit components Mj for each system. Then, the two systems are laid out with a minimum distance between the two. For example, assume that, in FIG. 10, the sizes of the circuit components Mj of the system A are S, L and S, and the sizes of the circuit components Mj of the system B are L, S and L. When the sizes of the circuit components Mj are in the above combination, the circuit components Mj of the system A are mounted by bringing their side surfaces into contact with each other, thereby to minimize the intervals therebetween. Next, in a similar manner, the circuit components Mj of the system B are mounted by bringing their side surfaces into contact with each other, thereby to minimize the intervals therebetween. Then, the system A and the system B are disposed by making the closest section between the two systems as close as possible. The system A and the system B may be disposed by making the distance ‘a’ between the closest parts of the system A and the system B zero.

Further, before dividing the circuit components into a plurality of systems, the circuit components may be separated into a few ranks according to the size tolerance of the circuit components. It is possible to reduce the intervals between the circuit components by mounting the circuit components using the circuit components of the same rank. For example, when the circuit components have their length and width ranked into three sizes of small (S), medium (M), and large (L), respectively, it is possible to divide the circuit components into nine ranks based on a combination of the length and width. When the circuit components of the same rank of size are mounted among the circuit components of the nine ranks of size, it is possible to minimize the intervals between the circuit components. The sizes of the circuit components may be divided into n ranks and the number of combination of ranks becomes n x n in this case.

[Third Embodiment]

In order to mount the circuit components Mj by bringing them into contact with each other, it is necessary to provide a predetermined reference. How this reference is determined will be explained in this embodiment.

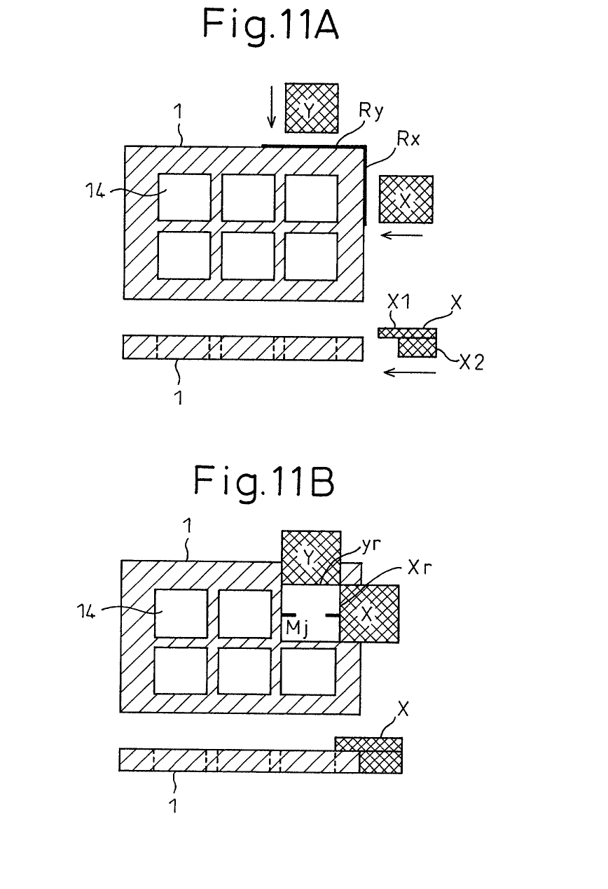

In FIG. 11A, a reference number 1 denotes a chassis that is provided with spaces 14 in which circuit components are disposed respectively. X denotes a reference tool for taking a standard in the X axis direction, and Y denotes a reference tool for taking a standard in the Y axis direction. On the chassis 1, there are also provided an end surface Rx that is used to take a reference in the X axis direction, and an end surface Ry that is used to take a reference in the Y axis direction. The drawing shown at a lower portion of FIG. 11A is a side view. As shown in the side view, the reference tool X has a claw section x1 to make a reference surface, and a base section x2 that is in contact with the reference end surface. The reference tool Y also has a claw section y1 to make a reference surface, and a base section y2 that is in contact with the reference end surface.

In order to take references in this structure, the reference tools X and Y are brought into contact with the reference end surfaces Rx and Ry, respectively. FIG. 11B shows a state wherein the reference tools X and Y are brought into contact with the reference end surfaces Rx and Ry respectively. End surfaces xr and yr of the reference tools X and Y that are in the contact state become the reference end surfaces in the x axis direction and the Y axis direction, respectively. A circuit component Mj is fixed to the chassis 1 by bringing the circuit component into contact with the reference surfaces xr and yr.

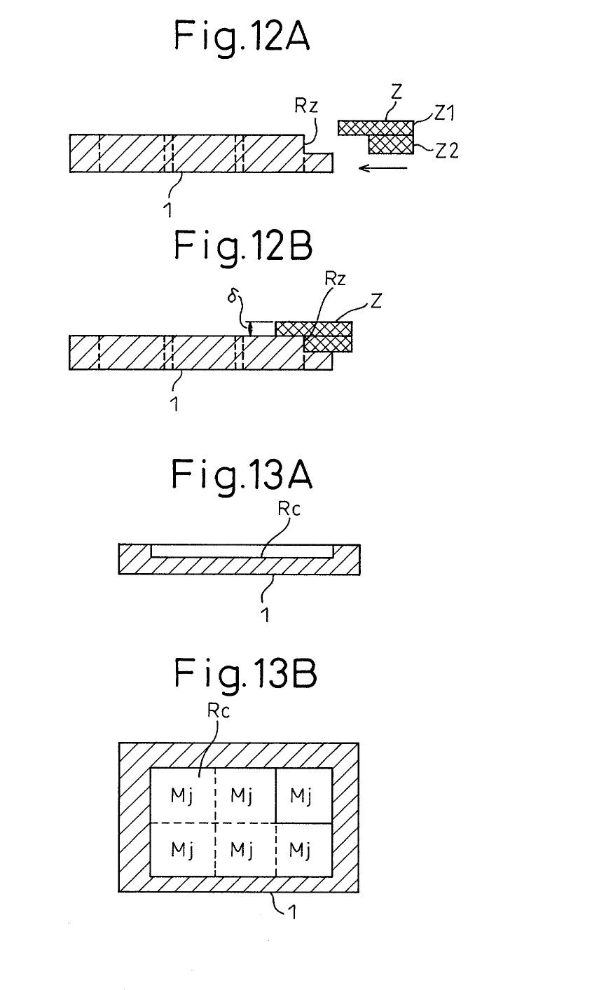

FIG. 12A and FIG. 12B show a modification of the embodiment explained with reference to FIG. 11. In this modification, a stage Rz is provided for reference end surfaces Rx and Ry of a chassis 1, as shown in FIG. 12A. A reference tool Z has a claw section z1 to make a reference surface and a base section z2 that is in contact with the reference end surface. As shown in FIG. 12B, the base section z2 of the tool Z is brought into contact with the bottom section and the side section of the stage Rz. The circuit component is fixed to the chassis 1 by using the end surface of the claw section z1 of the contacted tool z as a reference. In this case, it is also possible to prescribe the position of the claw z1 in the Z direction with the stage Rz, and to prescribe a height δ from the top surface of the chassis 1. When the height δ is assuredly prescribed, it is possible to prevent the circuit components from pilling up onto the tool or recessed from the tool, or the circuit components not being brought into contact with the reference surface of the tool, even when the circuit components are very thin. This stage Rz prescribes the height δ as less than the thickness of the circuit components.

FIG. 13A and FIG. 13B show an example in which a recess section Rc is provided on a chassis 1 in order to mount the circuit components by bringing them into contact with each other. As shown in FIG. 13A, the recess section Rc is provided on the chassis 1 in order to set a reference on the chassis. FIG. 13B shows a state wherein the circuit components Mj are mounted on the recess section Rc. As shown in FIG. 13B, the circuit component Mj is brought into contact with the side surface section at the right upper corner as a reference, and is fixed. An other circuit component is brought into contact with this fixed circuit component, and the circuit components shown by broken lines are sequentially mounted. The reference surface is not limited to the right upper corner of the recess section Rc, and may be another corner.

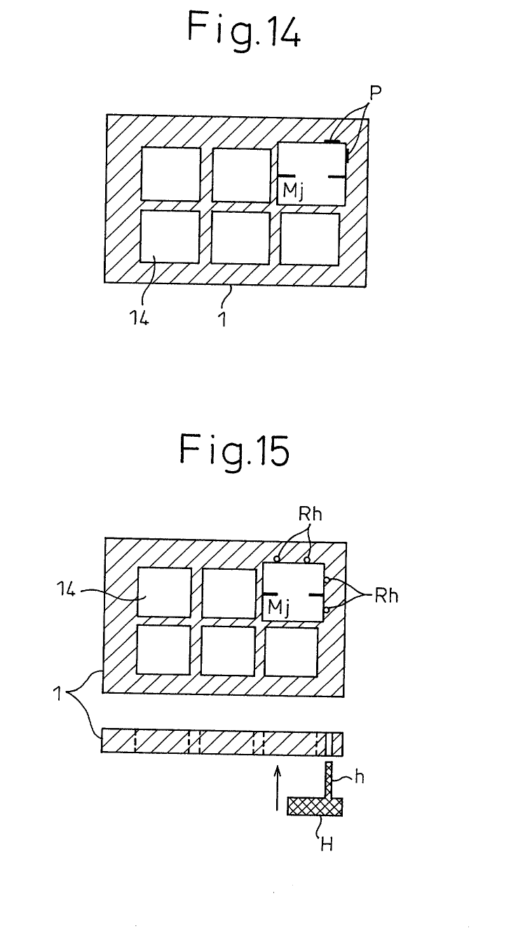

FIG. 14 shows another example in which a reference is provided for mounting circuit components Mj by bringing them into contact with each other. In this example, a plurality of projections p that become a reference are provided on a chassis 1 on which spaces 14 are provided to arrange the circuit components Mj. When a circuit component Mj is mounted by bringing it into contact with the projections p, the circuit component Mj is mounted at a reference position. The rest of the circuit components Mj are sequentially mounted by bringing them into contact with the mounted circuit component Mj.

FIG. 15 shows still another example in which a reference is provided for mounting circuit components Mj by bringing them into contact with each other. In this example, a plurality of holes Rh into which a contact reference tool is to be inserted are provided on a chassis 1 on which spaces 14 are provided to arrange the circuit components Mj. Prior to mounting a circuit component Mj, projections h that are provided on a tool H are inserted into the holes Rh from the back surface of the chassis 1. The circuit component Mj is brought into contact with the plurality of projections h that project from the front surface of the chassis 1, and the circuit component Mj is fixed. The rest of the circuit components Mj are sequentially mounted by bringing their side surfaces into contact with the fixed circuit component Mj.

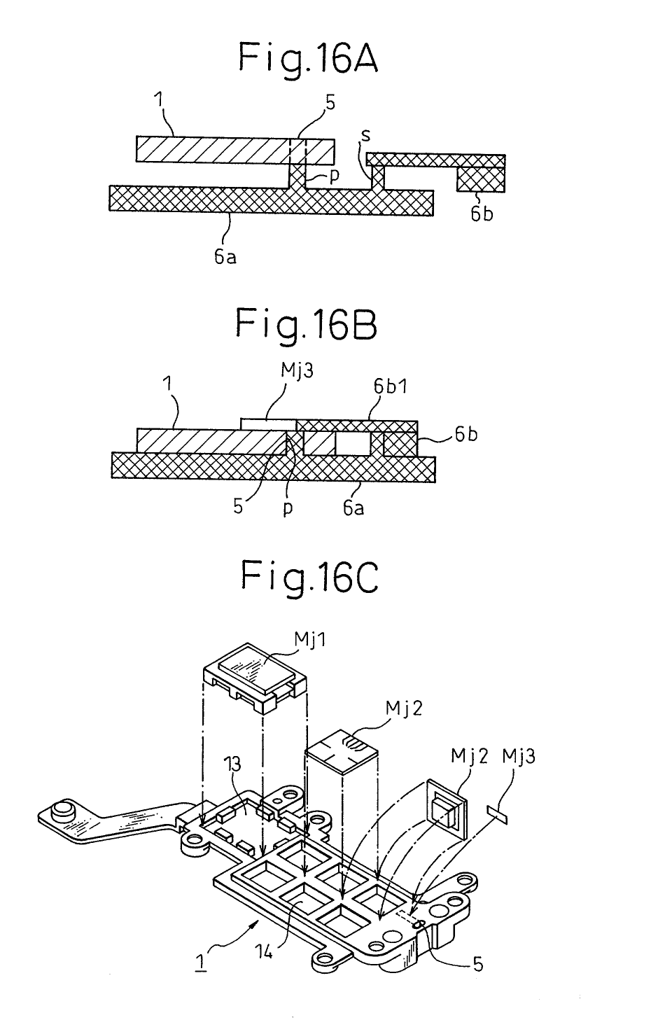

FIG. 16A to FIG. 16C show an example in which a reference position of circuit components Mj is set based on a connection point between the circuit components and an antenna, when the antenna is used as an input and output unit of a high frequency circuit like a radar apparatus.

A chassis 1 for a radar apparatus has a structure as shown in FIG. 16C. On the chassis 1 of the radar apparatus, there are provided an antenna connection hole (a waveguide), and fitting holes 13 and 14 as spaces for fitting circuit components Mj therein. An oscillator Mj1 is fitted into the fitting hole 13, and integrated circuits Mj2 that incorporate functions of a multiplier, an amplifier, an antenna sharing circuit, and a mixer are fitted into the fitting holes 14. A circuit component Mj3 like a microstrip line/waveguide conversion substrate is fitted into an antenna connection hole 5.

An example of fitting the circuit components Mj on the chassis 1 by using the antenna connection hole 5 as a reference will be explained. As shown in FIG. 16A, a reference number 5 denotes an antenna connection hole that is provided on a chassis 1, and 6a and 6b denote tools for setting a reference. The tool 6a is provided with a stopper s, and a projection p that is inserted into the antenna connection hole 5 of the chassis 1.

In this embodiment, as shown in FIG. 16B, the projection p of the tool 6a is first inserted into the hole 5 of the chassis 1. Next, the tool 6b is moved to the left in FIG. 16B until when the tool 6b is brought into contact with the stopper s. In this state, the circuit component Mj3 is brought into contact with a claw section 6b1 of the tool 6b, and is fixed. The circuit components Mj2 and Mj1 are mounted by sequentially bringing their side surfaces into contact with the fixed circuit component Mj3. While the hole 5 of the antenna connection section is used as a reference in this embodiment, it is also possible to use another hole that guarantees the positional precision relative to the hole 5 of the antenna connection section, as a reference.

[Fourth Embodiment]

According to the butt mounting structure of the present invention, it is necessary to fix the circuit components to the chassis by maintaining a previous position when the circuit components are mounted. However, when a general soldering method is used, the circuit components become buoyant on the solder when it is fused solder at the soldering time, and it is not possible to guarantee accurate mounting. A structure for fixing the circuit components onto the chassis in a state where the previous position when they are mounted is held according to the present invention will be explained next.

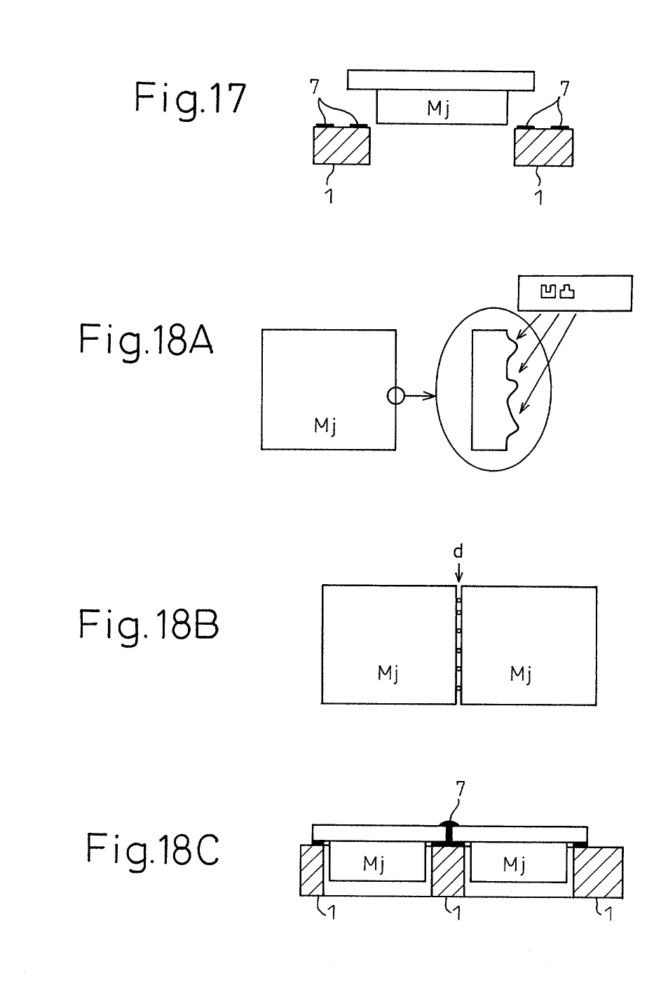

FIG. 17 shows an embodiment in which a conductive adhesive agent or an anisotropic conductive sheet 7 is used to fix circuit components. As shown in FIG. 17, when the conductive adhesive agent 7 is used to fix a circuit components Mj onto a chassis 1, the conductive adhesive agent 7 is coated on the chassis 1 in a predetermined quantity so as not to overflow from the adhering section. The conductive adhesive agent 7 is fixed by curing. When the anisotropic conductive sheet 7 is used, the anisotropic conductive sheet 7 is sandwiched between the circuit component Mj and the chassis, and this is thermally compressed.

At the time of butt mounting the circuit components Mj, when the conductive adhesive agent 7 is used to fix the circuit components Mj onto the chassis 1 as shown in FIG. 17, a fine gap d occurs at a contact position where the circuit components are brought into contact with each other as shown in FIG. 18B, as the surfaces of the circuit components Mj that are brought into contact with each other have fine unevenness as shown in FIG. 18A. The conductive adhesive agent 7 creeps along this gap, and is adhered to the high frequency pattern of the circuit components Mj as shown in FIG. 18C, which has a risk of damaging the performance. Therefore, in the present invention, at the time of butt mounting the circuit components, the surfaces of the circuit components Mj that are brought into contact with each other are ground, thereby to improve the close adhesion between the circuit components, and prevent creeping of the conductive adhesive agent 7.

[Fifth Embodiment]

In the butt mounting structure where the circuit components are brought into contact with each other according to the present invention, thermal stress is applied to the contact section of the circuit components Mj due to changes in temperature. This carries the risk of breaking the circuit components Mj, and degrading the performance, as well as reducing the reliability of the circuit components Mj. Therefore, in the present invention, the material of the chassis 1 is selected to match the coefficient of linear expansion of the circuit components Mj, and displacement of the contact section due to changes in temperature is thereby reduced.

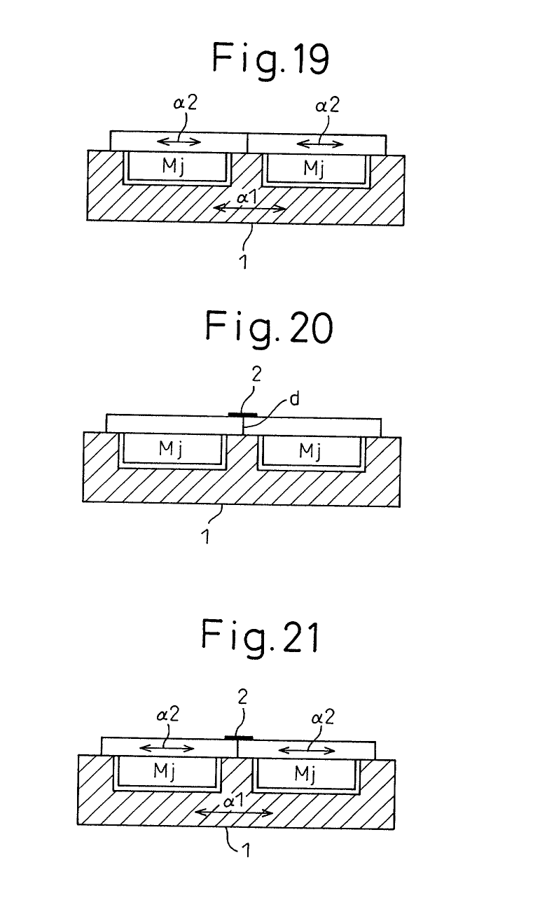

FIG. 19 shows an embodiment of the present invention. The material of a chassis 1 is selected such that the coefficient of linear expansion α1 of the chassis 1 is substantially the same as a coefficient of linear expansion α2 of circuit components Mj. For example, when the circuit components Mj are ceramic parts, iron nickel alloy is used for the material of the chassis 1. Based on this structure, the chassis 1 is expanded or compressed with substantially the same coefficient of linear expansion as that of the circuit components Mj. Therefore, thermal stress due to changes in temperature is not applied to the circuit components Mj. As a result, breaking of the circuit components Mj, deterioration in performance, and a reduction in the reliability of the circuit components Mj are prevented.

FIG. 20 is a view showing a mounting structure in which adjacent circuit components Mj are connected to each other with a gold ribbon line 2 according to the present invention, where the gold ribbon line 2 has no loop, and is bonded by ultrasonic wave welding, for example. By bonding the gold ribbon line 2 without having a loop, the height and length of the gold ribbon line 2 are reduced, which minimizes the influence on the line impedance, and reduce transmission loss.

However, when the adjacent circuit components Mj are connected to each other with the gold ribbon line 2 without having a loop, thermal stress is directly applied to the gold ribbon line 2 due to changes in temperature. This carries the risk that the performance of the circuit components will be degraded, and the reliability reduced. For example, when the gap d at the connection section between the circuit components Mj changes in size due to changes in temperature, there is a risk that the gold ribbon line 2 will be deformed and the performance degraded.

Therefore, in the present invention, the material of the chassis 1 is selected such that the coefficient of linear expansion α1 of the chassis 1 is substantially the same as the coefficient of linear expansion α2 of the circuit components Mj, as shown in FIG. 21. For example, when the circuit components Mj are ceramic circuit parts, iron nickel alloy is used for the material of the chassis 1. Based on this structure, there is little size change in the gap between the circuit components Mj attributable to a difference between the linear expansion of the circuit components Mj and that of the chassis 1, even when changes in temperature occur. As a result, the gold ribbon line 2 is not deformed due to the application of external force.

[Sixth Embodiment]

While the gold ribbon line 2 has been explained above as a structure for connecting the circuit components Mj, it is also possible to employ other structures, as follows.

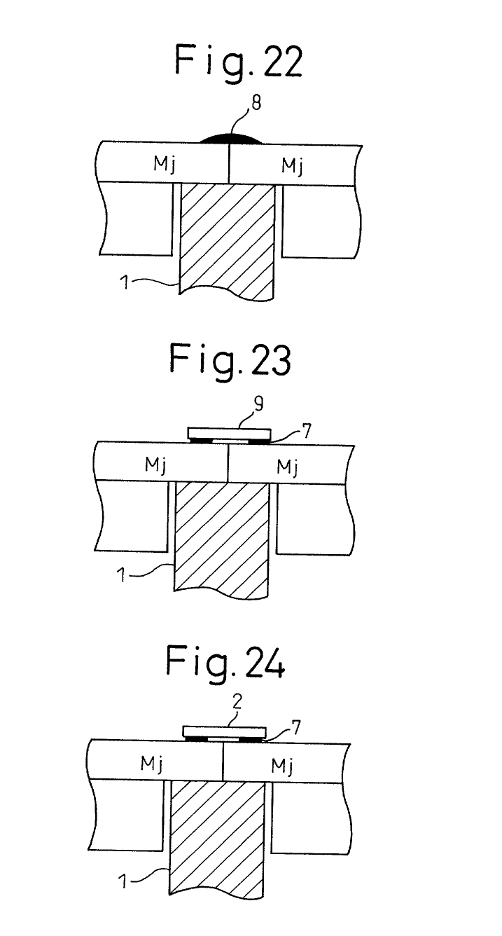

FIG. 22 shows a structure in which the circuit components are connected with a solder 8. In this example, circuit components Mj provided on a chassis 1 are connected with the solder 8. It is also possible to connect the circuit components by applying a conductive adhesive agent to a connection section, instead of the solder 8.

FIG. 23 is a view showing a structure in which circuit components Mj are connected with a metal plate 9, and the metal plate 9 is connected to the circuit components Mj with an anisotropic conductive sheet. In this example, the circuit components Mj provided on the chassis 1 are connected to each other with the metal plate 9, and the metal plate 9 is connected to the circuit components Mj with the anisotropic conductive sheet. It is also possible to connect the circuit components Mj to each other by welding the metal plate 9, instead of adhering the anisotropic conductive sheet as shown in FIG. 23.

FIG. 24 is a view showing a structure in which circuit components Mj are connected with a gold ribbon line 2, and the gold ribbon line 2 is connected to the circuit components Mj with a conductive adhesive agent 7 or an anisotropic conductive sheet 7. In this example, the circuit components Mj provided on the chassis 1 are connected to each other with the gold ribbon line 2, and the gold ribbon line 2 is connected to the circuit components Mj with the conductive adhesive agent 7 or the anisotropic conductive sheet 7.

Methods of mounting the high frequency circuit components in order to realize the above structures will be explained below.

(First Method)

According to a first method, in mounting a plurality of high frequency circuit components onto a chassis, each high frequency circuit component is adsorbed with a component-mounting nozzle. Next, each high frequency circuit component is conveyed onto the chassis or onto a guide fitted to the chassis with the component-mounting nozzle. At least one of the four side surfaces of the high frequency circuit component is brought into contact with the guide, thereby to position the high frequency circuit components on the chassis.

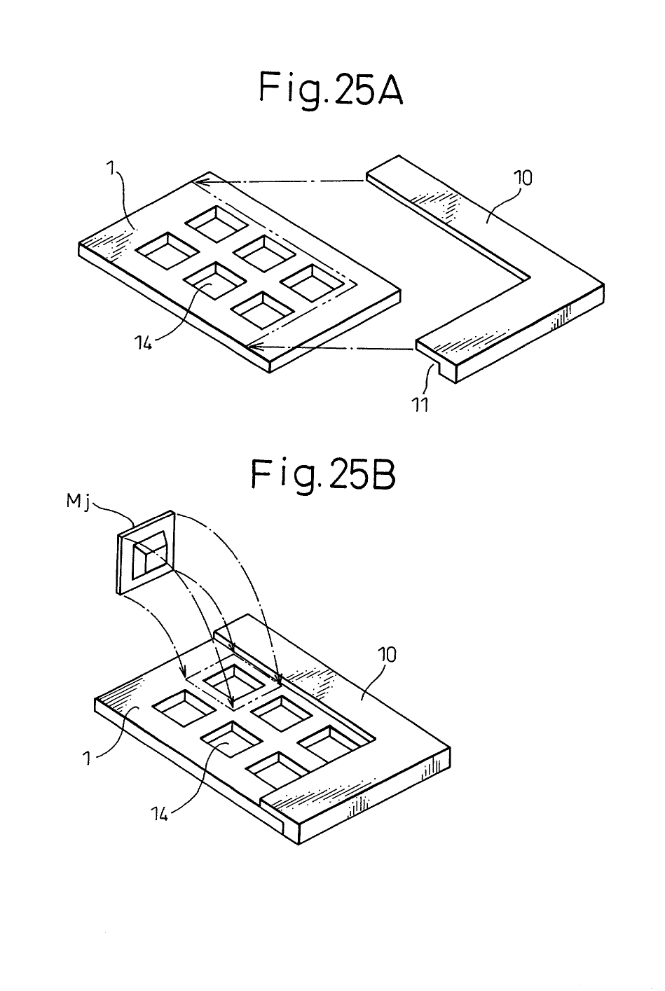

FIG. 25A shows one example of a chassis 1 on which a plurality of spaces 14 for fitting high frequency circuit components therein are provided, and a guide 10 that is fitted to this chassis 1 to position the high frequency circuit components. The guide 10 has a recess section 11 to be fitted to the edge section of the chassis 1. When the guide 10 is used, it is fitted to two adjacent sides of the chassis 1 as shown in FIG. 25B, high frequency circuit components Mj are mounted on the chassis 1 using the guide 10 as a reference.

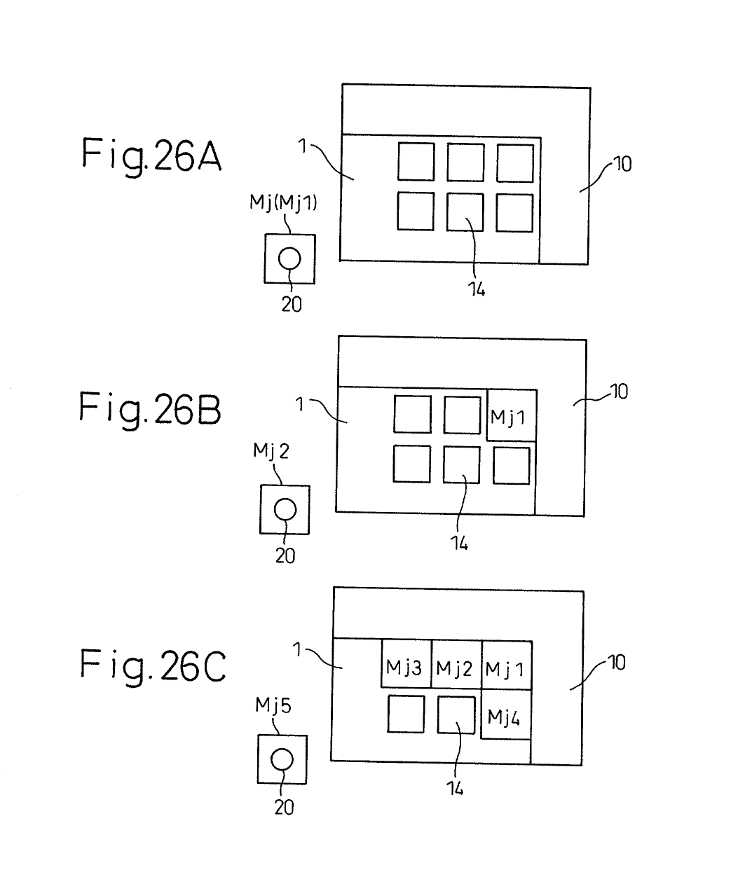

FIG. 26A to FIG. 26C are views for explaining stages of mounting high frequency circuit components according to the first method. Each high frequency circuit component Mj is adsorbed with a component-mounting nozzle 20 and is conveyed onto the chassis 1 that is fitted with the guide 10. A nozzle that adsorbs the high frequency circuit components Mj in a vacuum is generally used for the component-mounting nozzle 20. As shown in FIG. 26B, a first high frequency circuit component Mj1 is mounted on the chassis 1 in a state in which the high frequency circuit component is positioned by being brought into contact with the two sides of the guide 10. The next high frequency circuit component Mj2 is mounted on the chassis 1 in a state in which one of its sides is brought into contact with the guide 10 and one of its other sides is brought into contact with one side of the high frequency circuit component Mj1 already mounted. In other words, the high frequency circuit component Mj1 already mounted on the chassis 1 is used as a guide for the next high frequency circuit component Mj2.

Similarly, a third high frequency circuit component Mj3 and a fourth high frequency circuit component Mj4 are mounted on the chassis 1 in a state in which one side of each of these circuit components is brought into contact with the guide 10 and one other side of each of these circuit components is brought into contact with one side of the high frequency circuit component Mj1 and the high frequency circuit component Mj2 respectively that have already been mounted, as shown in FIG. 26C. A fifth high frequency circuit component Mj5 is mounted on the chassis 1 in a state in which it is positioned by being brought into contact with one side of the high frequency circuit component Mj2 and one side of the high frequency circuit component Mj4 that have already been mounted, as shown in FIG. 26C.

As explained above, according to the first method, the guide 10 that is fitted to the chassis 1 is used to position the high frequency circuit components Mj. At the same time, the sides of the high frequency circuit components that have already been mounted are also used as a guide to position the high frequency circuit component Mj to be mounted next.

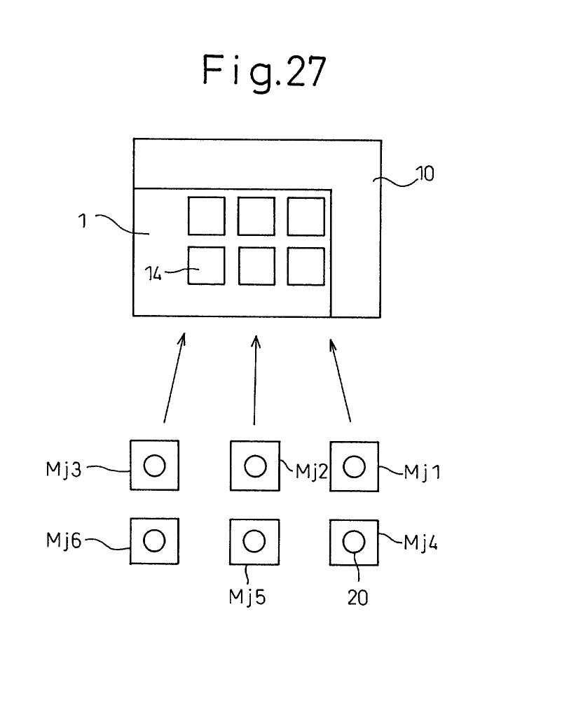

According to the first method explained with reference to FIG. 26A to FIG. 26C, the number of component-mounting nozzles 20 is one, and this nozzle 20 is used to convey each one of the high frequency circuit components Mj1 to Mj6 onto the chassis 1. According to a modification of the first method shown in FIG. 27, the component-mounting nozzles 20 provided are six, which is the same as the number of the high frequency circuit components that are mounted on the chassis 1. Therefore, in this modification, the six component-mounting nozzles 20 adsorb the high frequency circuit components Mj1 to Mj6 at the same time, and mount the high frequency circuit components Mj1 to Mj6 sequentially onto the chassis in a method similar to the first method explained with reference to FIG. 26A to FIG. 26C. As a result, the mounting time is reduced.

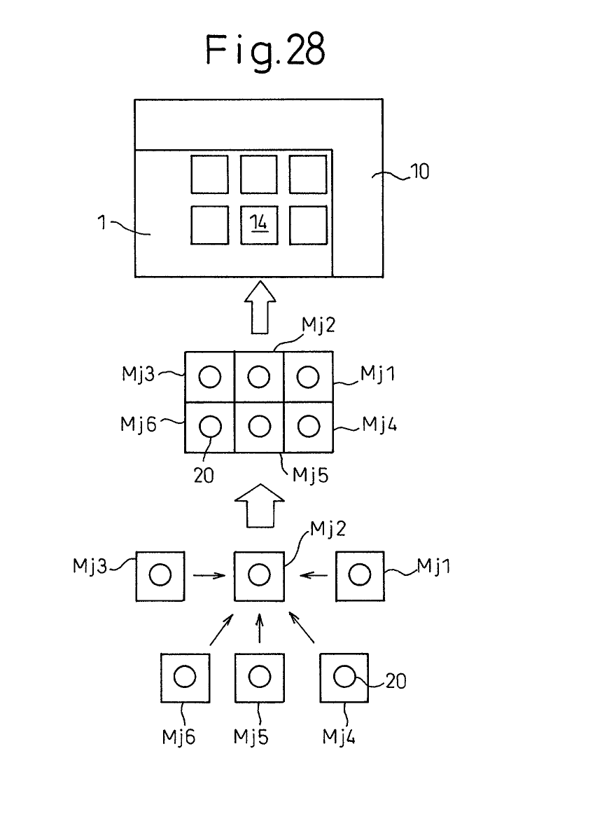

As an application of this modification of the first method, it is also possible to mount the high frequency circuit components as follows. As shown in FIG. 28, after the plurality of component-mounting nozzles 20 have sequentially adsorbed the high frequency circuit components Mj1 to Mj6, the plurality of component-mounting nozzles 20 position the high frequency circuit components Mj1 to Mj6 while keeping the high frequency circuit components Mj1 to Mj6 in the adsorbed state. After the high frequency circuit components Mj1 to Mj6 have been positioned, the plurality of component-mounting nozzles 20 collectively convey the high frequency circuit components Mj1 to Mj6 onto the chassis 1, and mount the high frequency circuit components by bringing them into contact with the guide 10.

(Second Method)

According to a second method, a plurality of actuators 30 that are provided around a chassis 1 are used to position high frequency circuit components Mj. The actuators 30 are disposed around the chassis 1 to face each other by sandwiching spaces 14 that are provided on the chassis 1. Each actuator 30 has a push rod 31 provided at its front end. The push rods 31 are arranged to be able to fine-adjust the distance they project from the actuator 30.

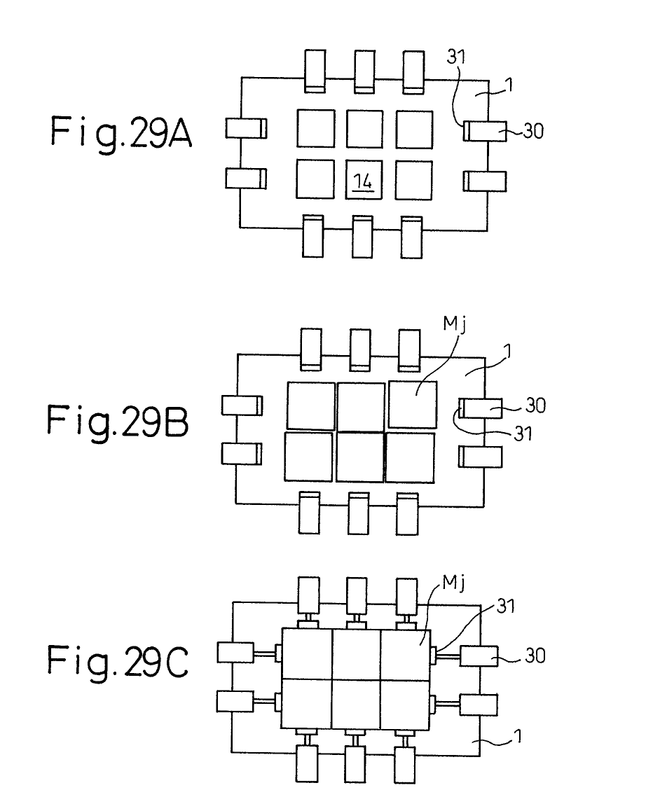

According to the second method, one or a plurality of component-mounting nozzles 20 are used to adsorb each of the high frequency circuit components Mj. As shown in FIG. 29B, the component-mounting nozzles 20 convey the high frequency circuit components Mj onto the chassis 1 and provisionally mount them. Then, as shown in FIG. 29C, the push rods 31 project from the actuators 30 that are disposed around the chassis 1, thereby to press the side surfaces of the high frequency circuit components Mj and adjust their positions on the chassis 1. It is possible to carry out this adjustment by monitoring the positions of circuit patterns provided on the upper surface of the high frequency circuit components Mj with a micro-camera or the like not shown. As a result, the high frequency circuit components Mj are positioned and mounted on the chassis 1. After the high frequency circuit components Mj have been mounted, the actuators 30 are removed.

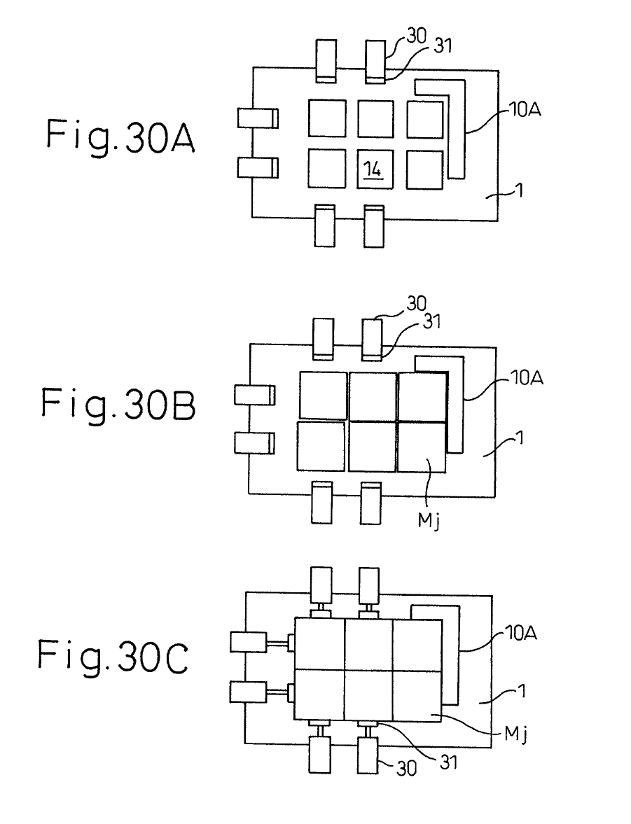

FIG. 30A to FIG. 30C show a first modification of the second method. The number of actuators 30 is decreased based on the provision of a guide 10A on a chassis 1. This guide 10A is provided in an L shape at the side of two spaces 14 at one side of the chassis 1, as shown in FIG. 30A.

According to this modification, one or a plurality of component-mounting nozzles 20 are used to adsorb each of the high frequency circuit components Mj. As shown in FIG. 30B, the component-mounting nozzles 20 convey the high frequency circuit components Mj onto the chassis 1 and provisionally mount them. Then, as shown in FIG. 30C, push rods 31 project from the actuators 30 that are disposed around the chassis 1, thereby to press the side surfaces of the high frequency circuit components Mj against the guide 10A and adjust the positions of the high frequency circuit components Mj on the chassis 1. As a result, the high frequency circuit components Mj are accurately positioned and mounted on the chassis 1. After the high frequency circuit components Mj have been mounted, the guide 10A and the actuators 30 are removed.

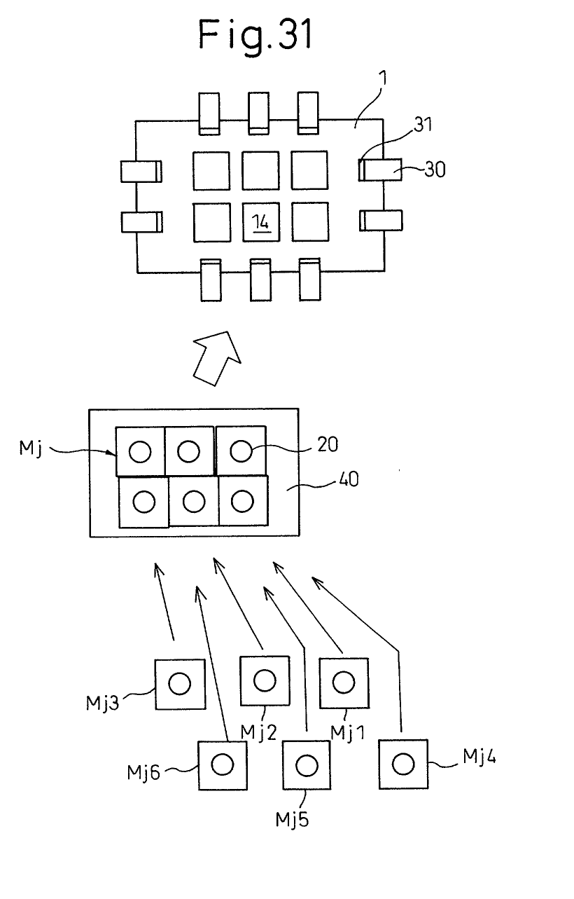

FIG. 31 shows a second modification of the second method, where a sub-stage 40 on which high frequency circuit components Mj are provisionally mounted is provided in front of a chassis 1. According to the second modification, a plurality of high frequency circuit components Mj1 to Mj6 are provisionally disposed on the sub-stage before being conveyed onto the chassis 1. One large component-mounting nozzle or a plurality of component-mounting nozzles 20 are used to collectively adsorb the plurality of high frequency circuit components Mj1 to Mj6 that are disposed provisionally, and convey them onto the chassis 1. The layout of actuators 30 shown in FIG. 31 is similar to that shown in FIG. 29A. Thereafter, the high frequency circuit components Mj1 to Mj6 are mounted on the chassis 1 in a procedure similar to that explained with reference to FIG. 29B and FIG. 29C.

(Third Method)

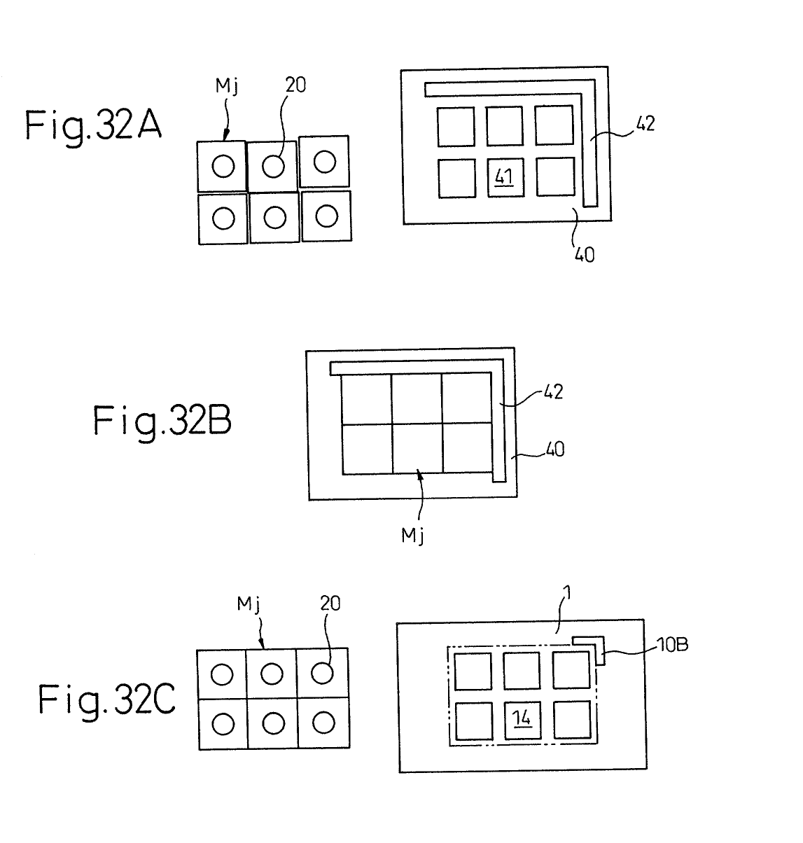

According to a third method, a plurality of high frequency circuit components are conveyed onto a sub-stage before being conveyed onto a chassis, and are positioned on the sub-stage. In the third method, a sub-stage 40 as shown in FIG. 32A is prepared in advance. On the sub-stage 40, there is provided an L-shaped guide 42 at the side of spaces 41 to fit the high frequency circuit components therein. A component-mounting nozzle 20 is used to adsorb each high frequency circuit component Mj, and convey it onto the sub-stage 40. The high frequency circuit components Mj that have been conveyed onto the sub-stage 40 are brought into contact with the guide 42 provided on the sub-stage 40 or the high frequency circuit components Mj already mounted, thereby to adjust the positions of the high frequency circuit components Mj, as shown in FIG. 32B.

A plurality of component-mounting nozzles 20 or one large component-mounting nozzle is used to collectively adsorb the plurality of position-adjusted high frequency circuit components Mj from above the sub-stage 40, and convey them onto a position shown by a two-point chain line on the chassis 1, thereby to collectively position the high frequency circuit components, as shown in FIG. 32C. In order to facilitate the positioning of the plurality of collectively-adsorbed high frequency circuit components Mj on the chassis 1, a small guide 10B may be provided on the chassis 1 in advance.

(Fourth Method)

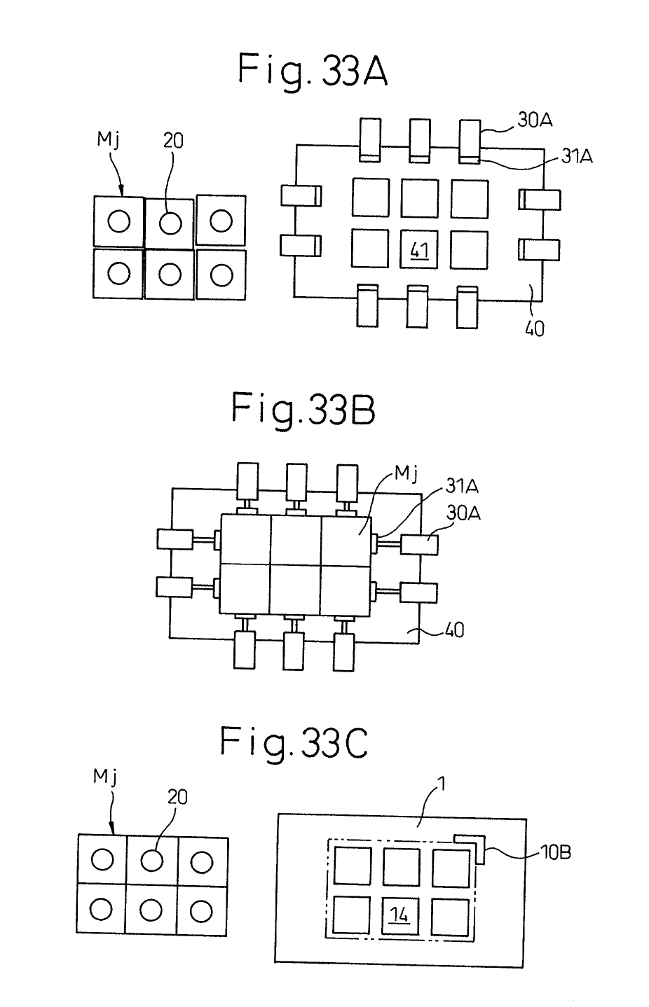

According to a fourth method, a plurality of high frequency circuit components are also conveyed onto a sub-stage before being conveyed onto a chassis, and are positioned on the sub-stage. In the fourth method, a sub-stage 40 as shown in FIG. 32A is prepared in advance. As shown in FIG. 33A, a plurality of actuators 30A are disposed around a sub-stage 40 to face each other by sandwiching spaces 41 on which the high frequency circuit components are to be fitted. The actuators 30A may be the same as the actuators 30 explained with reference to FIG. 29. Each actuator 30A has a push rod 31A provided at its front end. This push rod 31A is also arranged to be able to fine adjust the distance they project from the actuator 30A.

According to the fourth method, a component-mounting nozzle 20 is used to adsorb each high frequency circuit component Mj, and convey each high frequency circuit component Mj onto the sub-stage 40. The push rods 31A project from the actuators 30A disposed around the sub-stage 40 to press the side surfaces of the high frequency circuit components Mj that have been conveyed onto the sub-stage 40, thereby to adjust the positions of the high frequency circuit components Mj, as shown in FIG. 33B.

A plurality of component-mounting nozzles 20 or one large component-mounting nozzle is used to collectively adsorb the plurality of position-adjusted high frequency circuit components Mj from above the sub-stage 40, and convey them to a position shown by a two-point chain line on the chassis 1, thereby to collectively position them, as shown in FIG. 33C. In order to facilitate the positioning of the plurality of collectively-adsorbed high frequency circuit components Mj on the chassis 1, a small guide 10B may be provided on the chassis 1 in advance, like in the third method.

(Fifth Method)

A fifth method is a method of mounting high frequency circuit components when a high frequency circuit constructed of a plurality of high frequency circuit components has a plurality of systems. The plurality of systems indicates that when a high frequency circuit is used in a radar apparatus, the high frequency circuit has two systems, i.e. a transmission circuit that transmits a signal to an antenna, and a receiving circuit that guides the signal received by the antenna to a demodulation circuit, for example.

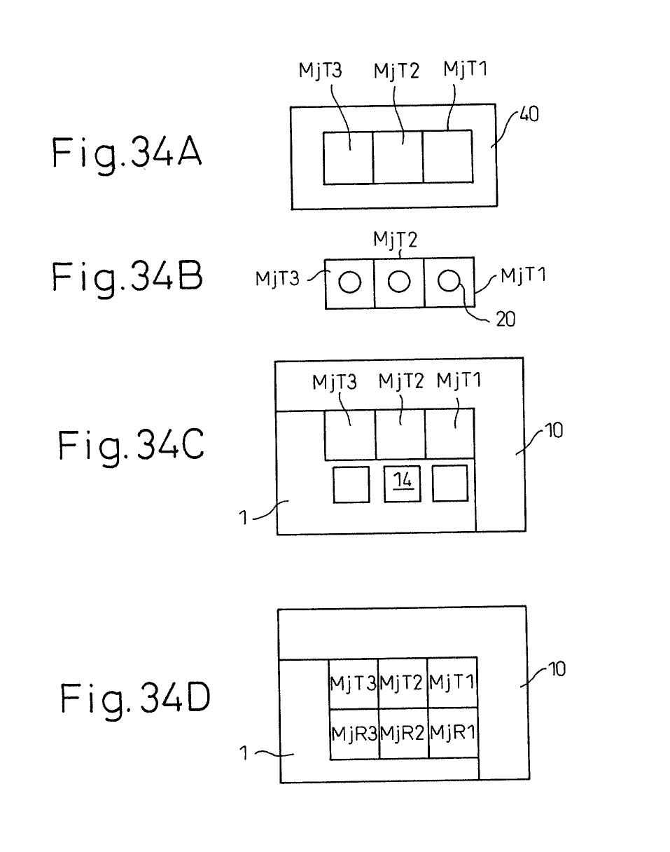

According to the fifth method, a plurality of high frequency circuit components Mj are provisionally disposed in advance on a sub-stage 40 for each component that belongs to a given system, as shown in FIG. 34A. For example, when the high frequency circuit is used in a radar apparatus, high frequency circuit components MjT1 to MjT3 that belong to the transmission system are provisionally disposed on the sub-stage 40.

Next, as shown in FIG. 34B, a plurality of component-mounting nozzles 20 or one component-mounting nozzle is used to collectively adsorb the high frequency circuit components MjT1 to MjT3, and convey them onto a chassis 1. As shown in FIG. 34C, the high frequency circuit components MjT1 to MjT3 on the chassis 1 are brought into contact with a guide 10 to fine-adjust the positions of the high frequency circuit components, thereby to position them on the chassis 1. The guide 10 used in the fifth method may be the same as the guide 10 used in the first method.

Thereafter, high frequency circuit components MjR1 to MjR3 that belong to the receiving system are provisionally disposed on the sub-stage 40. A plurality of component-mounting nozzles 20 or one component-mounting nozzle is used to collectively adsorb the high frequency circuit components MjR1 to MjR3, and convey them onto a chassis 1, in a similar manner to the above, as shown in FIG. 34D. The high frequency circuit components MjR1 to MjR3 that belong to the receiving system are positioned on the chassis 1 by bringing them into contact with the high frequency circuit components MjT1 to MjT3 that belong to the transmission system and already positioned on the chassis 1 and to the guide 10.

(Sixth Method)

A sixth method is also a method of mounting high frequency circuit components when a high frequency circuit constructed of a plurality of high frequency circuit components has a plurality of systems. The sixth method differs from the fifth method in the method of positioning the high frequency circuit components on the chassis 1.

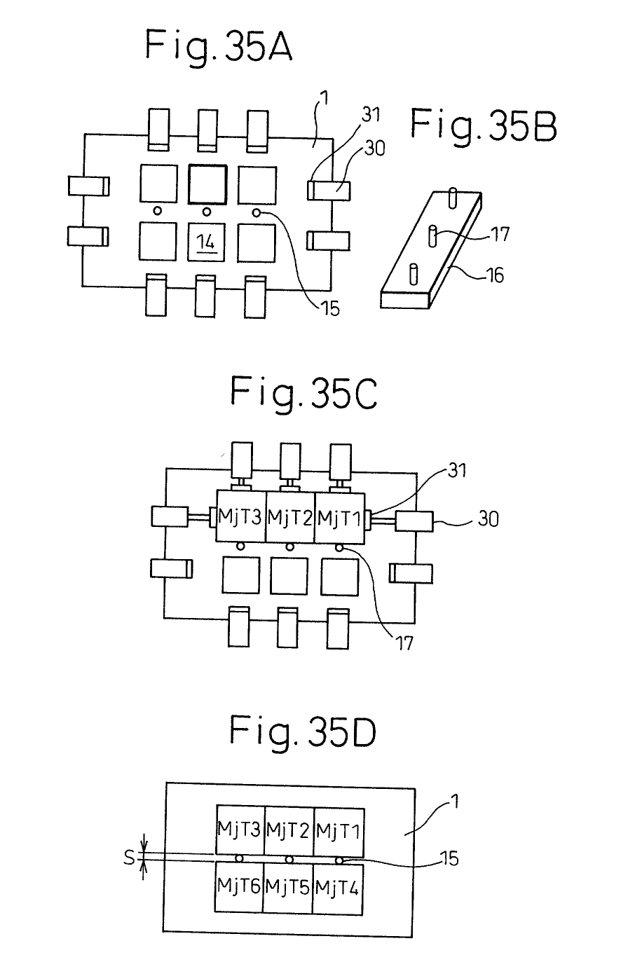

In the sixth method, a plurality of actuators 30 are provided on a chassis 1 like in the chassis 1 of the second method explained with reference to FIG. 29A. The chassis 1 of the sixth method differs from the chassis 1 of the second method in that a hole 15 for inserting a positioning pin therein is provided between a space 14 and a space 14 for each system, as shown in FIG. 35A. Guide pins 17 that are provided in projections on a tool 16 as shown in FIG. 35B are inserted into the holes 15 from the back surface of the chassis 1. The front ends of the guide pins 17 project from the front surface of the chassis 1.

In this state, high frequency circuit components Mj of a certain system provisionally disposed on a sub-stage 40 are disposed between the guide pins 17 and the actuators 30 for the components that belong to this system. For example, when a high frequency circuit is used in a radar apparatus, high frequency circuit components MjT1 to MjT3 that belong to a transmission system are provisionally disposed between the guide pins 17 and the actuators 30 on the sub-stage 40, as shown in FIG. 35C. Push rods 31 project from the actuators 30 to position the high frequency circuit components MjT1 to MjT3 of the transmission system with the guide pins 17 and the actuators 30.

Thereafter, high frequency circuit components MjR1 to MjR3 that belong to a receiving system are provisionally disposed on the sub-stage 40. A plurality of component-mounting nozzles 20 or one component-mounting nozzle is used to collectively adsorb the high frequency circuit components MjR1 to MjR3, and convey them onto a chassis 1, in a similar manner to the above. The high frequency circuit components MjR1 to MjR3 that belong to the receiving system are provisionally disposed between the guide pins 17 and the actuators 30 on the sub-stage 40, like the high frequency circuit components MjT1 to MjT3 that belong to the transmission system. The push rods 31 project from the actuators 30 to position the high frequency circuit components MjR1 to MjR3 of the receiving system with the guide pins 17 and the actuators 30.

After the high frequency circuit components MjT1 to MjT3 of the transmission system and the high frequency circuit components MjR1 to MjR3 of the receiving system have been positioned on the chassis 1, the tool 16 having the guide pins 17 is removed from the chassis 1, as shown in FIG. 35D. In the sixth method, a slight gap S occurs between the high frequency circuit components MjT1 to MjT3 of the transmission system and the high frequency circuit components MjR1 to MjR3 of the receiving system. However, the gap between the different signal systems has no adverse influence on the signal transmission.

(Seventh Method)

A seventh method is also a method of mounting high frequency circuit components when a high frequency circuit constructed of a plurality of high frequency circuit components has a plurality of systems. The seventh method differs from the sixth method in that a transmission/reception module having the wiring of a transmission system and the wiring of a receiving system on the same surface is disposed on a chassis, and that the method of positioning the high frequency circuit components on the chassis is different. In the seventh method, it is not necessary to use a sub-stage.

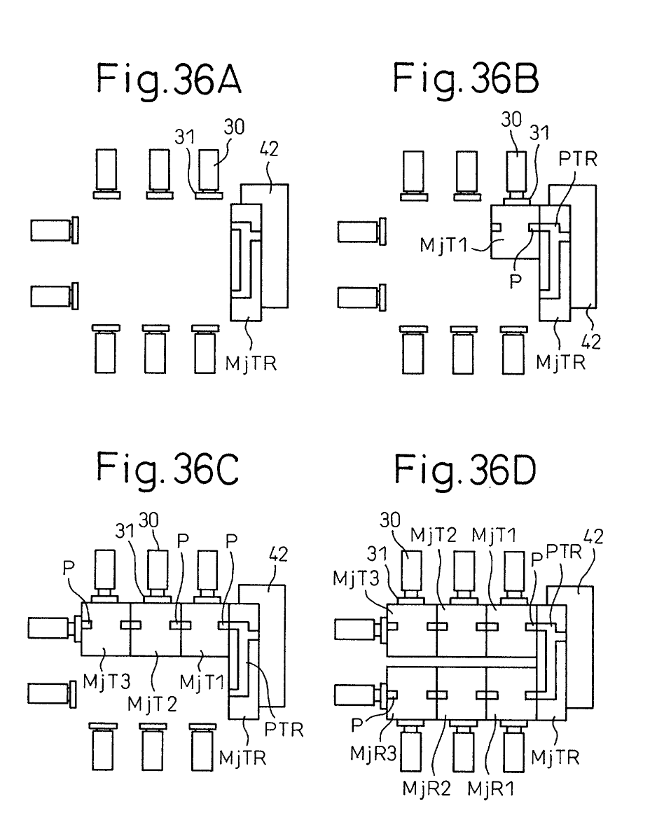

In the seventh method, a chassis is used where the two actuators 30 disposed at the right side of the chassis 1 in the second method explained with reference to FIG. 29A is replaced by a guide 42. FIG. 36A to FIG. 36D show the seventh method. In these drawings, the chassis is omitted, and only actuators 30 and the guide 42 are shown.

The chassis of the seventh method further differs from the chassis 1 of the second method in that a vacuum adsorption mechanism is provided on the push rod 31 of each actuator 30 so that the actuators 30 can not only push the high frequency circuit components but also pull them. Based on the adsorption mechanism of the actuators 30, it is possible to fine-adjust the positions of the high frequency circuit components.

When the adsorption mechanism is not provided on the actuators 30, the guide pins provided on the tool may be used, as explained with reference to FIG. 35A. The guide pins are inserted from the back surface of the chassis into the holes provided between the spaces of each system on the chassis. The front ends of the guide pins project from the front surface of the chassis.

According to the seventh method, when a high frequency circuit is used in a radar apparatus, first, a component-mounting nozzle not shown is used to mount a transmission/reception module MjTR as a high frequency circuit provided with the wiring of the transmission system and the receiving system, onto the chassis, by bringing this module into contact with the guide 42, as shown in FIG. 36A. Next, as shown in FIG. 36B, the component-mounting nozzle brings a high frequency circuit component MjT1 that belongs to the transmission system into contact with the transmission/reception module MjTR. In this state, the push rod 31 project from the actuator 30 to adsorb the high frequency circuit component MjT1 of the transmission system. Then, the push rod 31 is moved to slide the high frequency circuit component MjT1 along the transmission/reception module MjTR, thereby to position a circuit pattern P that is formed on the surface of the high frequency circuit component MjT1 with a circuit pattern PTR that is formed on the surface of the transmission/reception module MjTR.

Similarly, the component-mounting nozzle is used to mount high frequency circuit components MjT2 and MjT3 that belong to the transmission system onto the chassis by bringing these high frequency circuit components into contact with the high frequency circuit component MjT1. In this state, as shown in FIG. 36C, the push rods 31 project from the actuators 30 to adsorb the high frequency circuit components MjT2 and MjT3 of the transmission system. Then, the push rods 31 are moved to position a circuit pattern P of the high frequency circuit components MjT1 with a circuit pattern P of the high frequency circuit components MjT2, and position the circuit pattern P of the high frequency circuit components MjT2 with a circuit pattern P of the high frequency circuit components MjT3.

After the high frequency circuit components MjT1 to MjT3 of the transmission system have been positioned with the actuators 30, a plurality of component-mounting nozzles are used to adsorb high frequency circuit components MjR1 to MjR3 that belong to the receiving system respectively, and convey these high frequency circuit components onto the chassis, as shown in FIG. 36D. The push rods 31 project from the actuators 30 to position the high frequency circuit components MjR1 to MjR3 that belong to the receiving system in a similar manner to that for the high frequency circuit components MjT1 to MjT3 that belong to the transmission system. Based on this positioning, the circuit pattern PTR of the transmission/reception module MjTR is positioned with a circuit pattern P of the high frequency circuit component MjR1, the circuit pattern P of the high frequency circuit component MjR1 is positioned with a circuit pattern P of the high frequency circuit component MjR2, and the circuit pattern P of the high frequency circuit component MjR2 is positioned with a circuit pattern P of the high frequency circuit component MjR3, respectively.

Thus the circuit patterns P of the high frequency circuit components MjT1 to MjT3 that belong to the transmission system, the circuit patterns P of the high frequency circuit components MjR1 to MjR3 that belong to the receiving system, and the circuit pattern PTR of the transmission/reception module MjTR, are positioned. In the seventh method, a slight gap is provided as a positioning adjustment space between the high frequency circuit components MjT1 to MjT3 of the transmission system and the high frequency circuit components MjR1 to MjR3 of the receiving system. However, the gap between the different signal systems has no adverse influence on the signal transmission.

(Eighth Method)

An eighth method is also a method of mounting high frequency circuit components when a high frequency circuit constructed of a plurality of high frequency circuit components has a plurality of systems. In the fifth and sixth methods, a plurality of high frequency circuit components Mj are provisionally disposed on the sub-stage 40 for each component that belongs to a given system in advance, and these high frequency circuit components are accurately positioned for each system on the chassis 1. On the other hand, the eighth method differs from these methods in that a plurality of high frequency circuit components Mj are arranged on the sub-stage 40 for each component that belongs to a given system and are accurately positioned for each system on the sub-stage 40 in advance.

In the eighth method, a plurality of systems will also be explained as a signal transmission system and a signal receiving system.

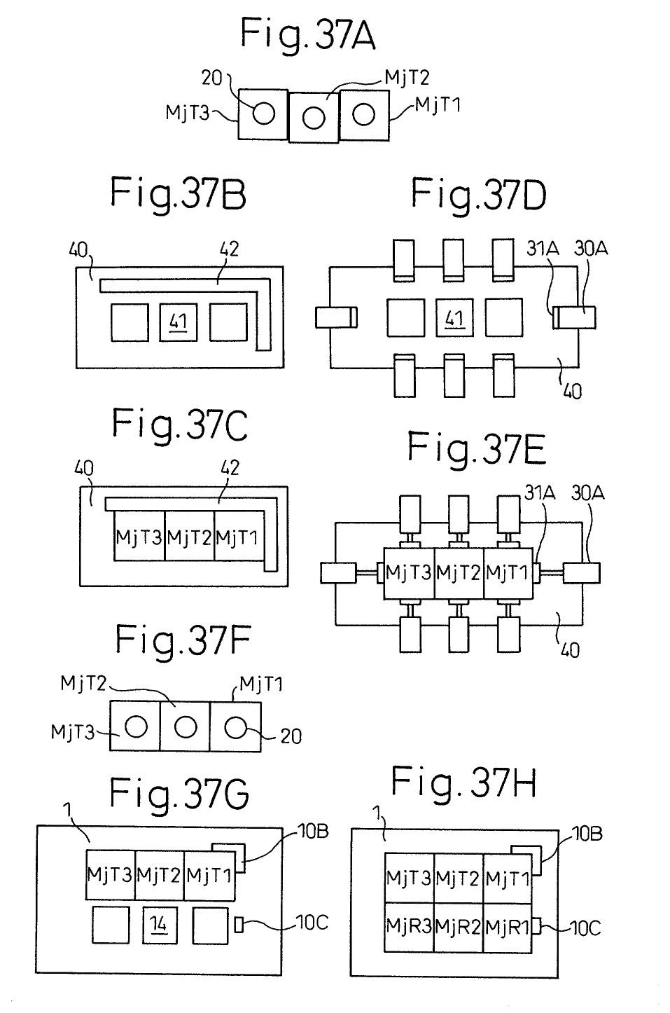

According to the eighth method, first, as shown in FIG. 37A, a plurality of component-mounting nozzles 20 or one component-mounting nozzle is used to collectively adsorb high frequency circuit components MjT1 to MjT3 that belong to the transmission system, and convey them onto a sub-stage 40 that is provided with a guide 42 as shown in FIG. 37B. As shown in FIG. 37C, the high frequency circuit components MjT1 to MjT3 on the sub-stage 40 are brought into contact with the guide 42 to adjust their positions, thereby to position the high frequency circuit components MjT1 to MjT3 on the chassis 1. The guide 42 used in the eighth method may be the same as the guide 42 used in the third method.

Next, as shown in FIG. 37F, the plurality of component-mounting nozzles 20 or one component-mounting nozzle is used to collectively adsorb the high frequency circuit components MjT1 to MjT3 of the transmission system that have been positioned on the sub-stage 40, and convey them onto a chassis 1 to collectively position the high frequency circuit components of the transmission system. In order to facilitate the positioning of the collectively-adsorbed high frequency circuit components MjT1 to MjT3 of the transmission system, a small guide 10B may be provided on the chassis 1 in advance.

Thereafter, high frequency circuit components MjR1 to MjR3 that belong to the receiving system are positioned in a similar manner. A plurality of component-mounting nozzles 20 or one component-mounting nozzle is used to collectively adsorb these high frequency circuit components, and convey them onto the chassis 1, as shown in FIG. 37H. The high frequency circuit components MjR1 to MjR3 that belong to the receiving system are mounted adjacent to the high frequency circuit components MjT1 to MjT3 of the transmission system that have already been mounted on the chassis 1. It is not necessary to bring the high frequency circuit components MjR1 to MjR3 that belong to the receiving system into close contact with the high frequency circuit components MjT1 to MjT3 of the transmission system, unlike the above methods, i.e. there may be a slight gap between the two systems. In order to facilitate the positioning of the collectively-adsorbed high frequency circuit components MjR1 to MjR3 of the receiving system, a small guide 10C may be provided on the chassis 1 in advance.

(Ninth Method)

A ninth method is also a method of mounting high frequency circuit components when a high frequency circuit constructed of a plurality of high frequency circuit components has a plurality of systems. Like in the eighth method, a plurality of high frequency circuit components Mj are arranged on a sub-stage 40 for each component that belongs to a given system and are accurately positioned for each system on the sub-stage 40 in advance. In the ninth method, a plurality of systems will also be explained as a signal transmission system and a signal receiving system.

According to the ninth method, first, as shown in FIG. 37A, a plurality of component-mounting nozzles 20 or one component-mounting nozzle is used to collectively adsorb high frequency circuit components MjT1 to MjT3 that belong to the transmission system, and convey them onto a sub-stage 40 that is provided with actuators 30A around the sub-stage 40 as shown in FIG. 37D. As shown in FIG. 37E, push rods 31A are made to project from the actuators 30A to adjust the positions of the high frequency circuit components MjT1 to MjT3 on the sub-stage 40, thereby to position them on the chassis 1. The actuators 30A used in the ninth method may be the same as the actuators 30A used in the fourth method.

Next, as shown in FIG. 37F, the plurality of component-mounting nozzles 20 or one component-mounting nozzle is used to collectively adsorb the high frequency circuit components MjT1 to MjT3 of the transmission system that have been positioned on the sub-stage 40, and convey them onto a chassis 1 to collectively position the high frequency circuit components of the transmission system. Thereafter, high frequency circuit components MjR1 to MjR3 that belong to the receiving system are positioned on the sub-stage 40, and are then positioned on the chassis 1. These steps are similar to the steps of the eighth method, and therefore further detailed explanation will be omitted.

Last, a structure of a mounting apparatus that mounts the high frequency circuit components to realize the above mounting methods will be explained.

(First Structure)

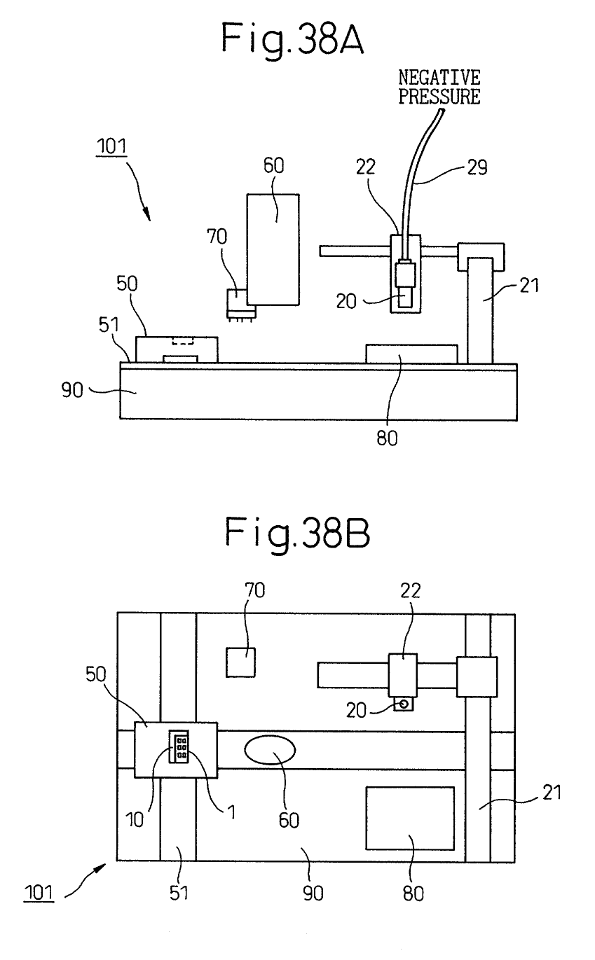

FIG. 38A is a side view of a mounting apparatus for high frequency circuit components in a first mode of a first structure according to the present invention. FIG. 38B is a top plan view of the mounting apparatus shown in FIG. 38A. A mounting apparatus 101 in the first mode has a mounting base 90, on which there are an X-Y robot 21, an X-Y table 51, and a component tray 80. Above the mounting base 90, there are a micro-camera 60, and a pressing mechanism 70.

The X-Y robot 21 is provided with a Z-axis actuator 22 that can move above the mounting base 90. The Z-axis actuator 22 is fitted with a component-mounting nozzle 20, which can approach and move away from the mounting base 90, based on the movement of the Z-axis actuator 22. The inside of the component-mounting nozzle 20 is placed in a vacuum state through a vacuum pipe 29 based on a vacuum source not shown. The component-mounting nozzle 20 can adsorb high frequency circuit components Mj based on vacuum adsorptive force. The component tray 80 on which the high frequency circuit components are mounted is provided within the movable range of the component-mounting nozzle 20 above the mounting base 90.

On the X-Y table 51, there is fitted a mounting stage 50 that can move on the mounting base 90. A chassis 1 on which the high frequency circuit components are mounted is fitted on the mounting stage 50. In the first mode, a guide 10 for positioning the high frequency circuit components is fitted on the chassis 1.

Although not shown in the drawing, on the mounting apparatus 101 for the high frequency circuit components, there are also provided a control unit that utilizes a computer to control the operation of the X-Y robot 21, the operation of the Z-axis actuator 22, a dgree of negative pressure, the operation of the X-Y table, and the operation of the pressing mechanism 70, a control panel, and a display unit. Explanation of these units and operation will be omitted.

According to the mounting apparatus 101 for the high frequency circuit components in the first mode of the first structure of the present invention, the chassis 1 on which the high frequency circuit components are mounted and the guide 10 are first installed on the mounting stage 50. In this state, the mounting stage 50 is moved within the movable range of the X-Y robot 21, based on the operation of the X-Y table 51. Next, the X-Y robot 21 operates to adsorb the high frequency circuit components from the component tray 80 with the component-mounting nozzle 20, and convey them directly onto the chassis 1 on the mounting stage 50. According to the mounting apparatus 101 for the high frequency circuit components in the first mode of the first structure, the high frequency circuit components that have been adsorbed with the component-mounting nozzle 20 are guided by the guide 10 and are mounted on the chassis 1. After the high frequency circuit components are inspected with the micro-camera 60, they are fixed onto the chassis 1 with the pressing mechanism 70.

According to the mounting apparatus 101 for the high frequency circuit components in the first mode of the first structure, it is possible to employ a modification of a structure such that a plurality of component-mounting nozzles 20 are provided, or a positioning mechanism of high frequency circuit components is provided in a plurality of component-mounting nozzle 20, as explained in the above methods.

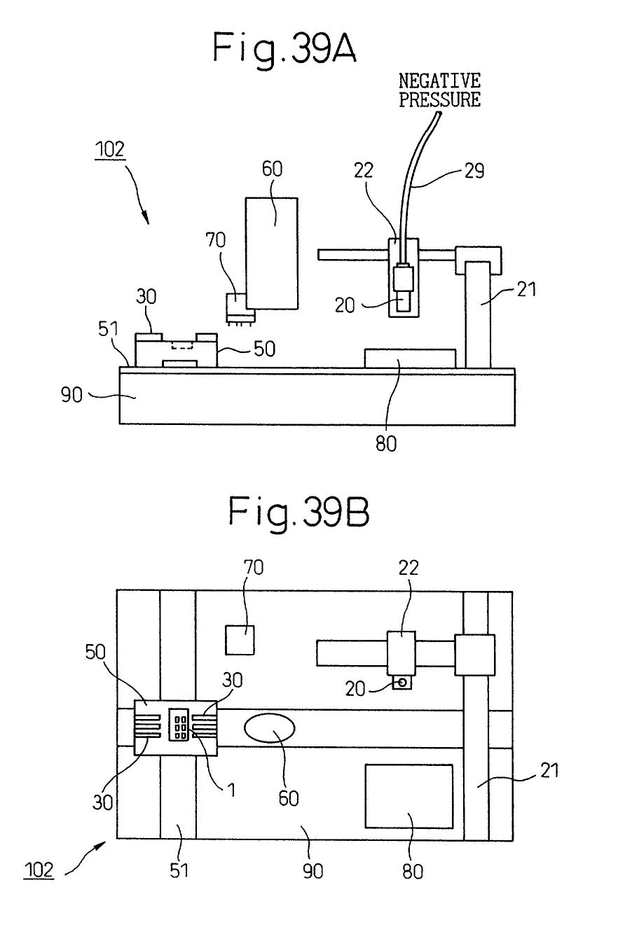

FIG. 39A is a side view of a mounting apparatus 102 for high frequency circuit components in a second mode of the first structure according to the present invention. FIG. 39B is a top plan view of the mounting apparatus 102 shown in FIG. 39A. The mounting apparatus 102 in the second mode differs from the mounting apparatus 101 in the first mode only in that while the chassis 1 fitted with the guide 10 is disposed on the mounting stage 50 in the first mode, a plurality of actuators 30 for positioning the high frequency circuit components are disposed on the mounting stage 50 in the second mode. Constituent elements of the second mode that are identical to those of the first mode will be designated by like reference numbers, and explanation of these elements and operation will be omitted.

According to the mounting apparatus 101 for the high frequency circuit components in the second mode of the first structure of the present invention, only the chassis 1 is fitted on the mounting stage 50. In this state, the mounting stage 50 is moved within the movable range of the X-Y robot 21, based on the operation of the X-Y table 51. Next, the X-Y robot 21 operates to adsorb the high frequency circuit components from the component tray 80 with the component-mounting nozzle 20, and convey them directly onto the chassis 1 on the mounting stage 50. According to the mounting apparatus 102 for the high frequency circuit components in the second mode of the first structure, when all the high frequency circuit components have been provisionally disposed on the chassis 1, the mounting stage 50 moves according to the X-Y table 51, and the chassis 1 is positioned immediately below the micro-camera 60. The high frequency circuit components are positioned with the actuators 30, while their positions on the chassis 1 are checked using the micro-camera 60, in the manner as described above. Then, the chassis 1 is moved to the pressing mechanism 70 by the X-Y table 51, and the high frequency circuit components are fixed onto the chassis 1 with the pressing mechanism 70.

(Second Structure)

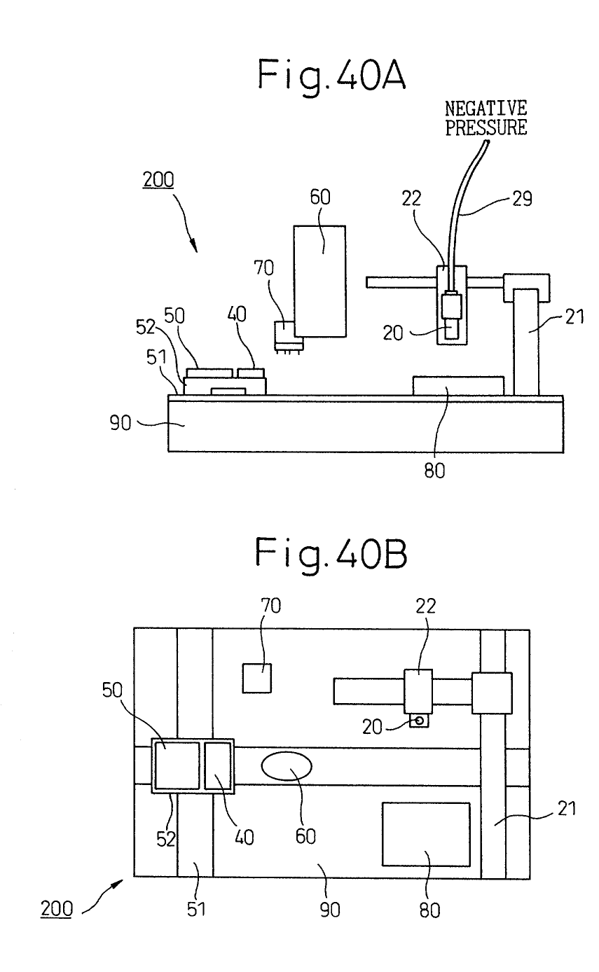

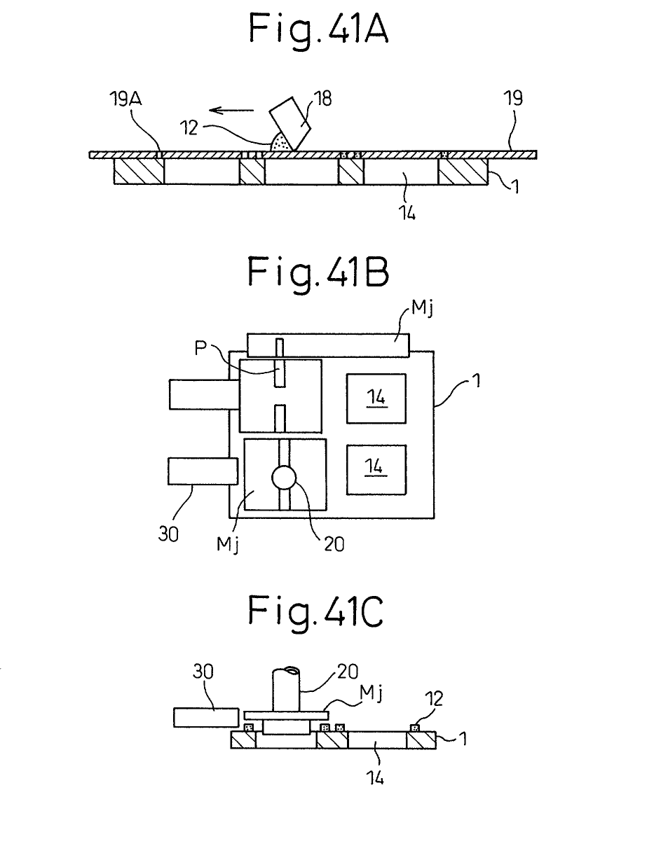

FIG. 40A is a side view showing an outline of a second structure of a mounting apparatus 200 for high frequency circuit components according to the present invention. FIG. 40B is a top plan view of the mounting apparatus 200 shown in FIG. 40A. The mounting apparatus 200 of the second structure differs from the mounting apparatuses 101 and 102 of the first structure in that while only the mounting stage 50 is provided on the X-Y stable 51 in the first structure, a common stage 52 is provided on an X-Y table in the second structure, and that a mounting stage 50 and a sub-stage 40 are provided on the common stage 52.

Although not shown in the drawing, the mounting apparatus of the second structure has the following modes of structure in order to implement the above-described methods: (1) a structure in which a guide 10 is provided on a mounting stage 50, (2) a structure in which actuators 30 are provided on the mounting stage 50, (3) a structure in which a guide 42 is provided on a sub-stage 40, (4) a structure in which actuators 30A are provided on the sub-stage 40, and (5) a plurality of component-mounting nozzles are provided. It is also possible to combine these structures. As these structures have already been explained in the above methods, explanation of them will be omitted here.

According to the second structure, high frequency circuit components are conveyed from a component tray 80 onto the sub-stage 40 with a component-mounting nozzle 20. The high frequency circuit components are conveyed from the sub-stage 40 onto a chassis 1 on the mounting stage 50 with the component-mounting nozzle 20. The operation of the mounting apparatus 200 for high frequency circuit components of the second structure has already been explained in detail in the above mounting method, and therefore explanation of this operation will be omitted.

The procedure of mounting high frequency circuit components Mj onto the chassis 1 with the mounting apparatus 102 of a second mode of the first structure will be explained among the mounting apparatuses of the above structures.

In the process of mounting the high frequency circuit components Mj onto the chassis 1, an adhesive agent is first coated onto the chassis 1 to fix the high frequency circuit components Mj thereto. A screen 19 that has holes 19A at predetermined positions to allow the adhesive agent 12 to pass through is mounted on the chassis 1 in a set position. The adhesive agent 12 is coated onto the chassis 1 using a squeezer 18, as shown in FIG. 41A.

FIG. 41B and FIG. 41C are views for explaining a state of provisionally mounting the high frequency circuit components Mj onto the chassis 1 using the component-mounting nozzle 20. FIG. 41B and FIG. 41C show a state in which one high frequency circuit component Mj has already been positioned on the chassis 1, and the next high frequency circuit component Mj is about to be positioned. When this next high frequency circuit component Mj has been conveyed to the vicinity of the mounting position on the chassis 1 with the component-mounting nozzle 20, the component-mounting nozzle 20 descends towards a chassis, and stops at a height defined by the sum of the thickness of coating the adhesive agent 12 and a few dozens of μm.

It is possible to adjust the stop position of the component-mounting nozzle 20 by measuring the height from the chassis 1 of the component-mounting nozzle 20 or the height from the top surface of the high frequency circuit component Mj already mounted, with a laser measuring unit that is fitted to a Z-axis actuator 22.

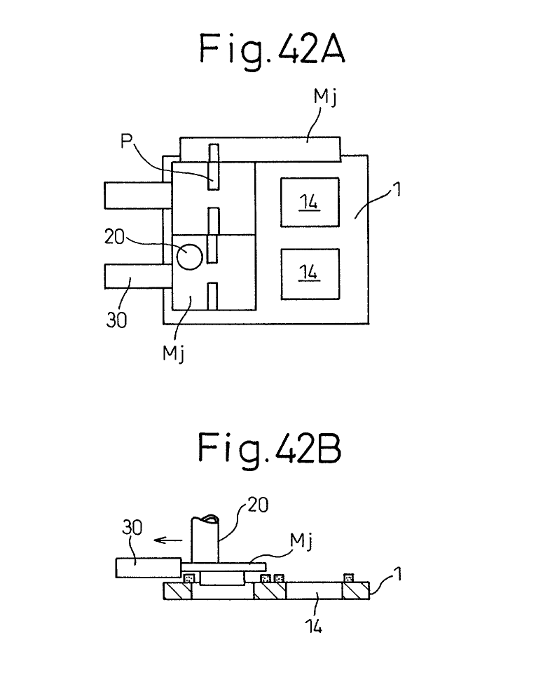

In this state, the component-mounting nozzle 20 moves the adsorbed high frequency circuit component Mj to bring two sides of this high frequency circuit component Mj into contact with the high frequency circuit component Mj that has already been provisionally mounted and the actuator 30, as shown in FIG. 42A and FIG. 42B. When the two sides of the high frequency circuit component Mj adsorbed by the component-mounting nozzle 20 have been brought into contact with the high frequency circuit component Mj that has already been provisionally mounted and the actuator 30, movement of the high frequency circuit component Mj stops. However, the component-mounting nozzle 20 continues to move in the proceeding direction due to inertia. As the high frequency circuit component Mj has been adsorbed in vacuum by the component-mounting nozzle 20, the component-mounting nozzle 20 slides on the upper surface of the high frequency circuit component with the high frequency circuit component Mj kept adsorbed. Consequently, the high frequency circuit component is mounted on the chassis 1 without stress.

When the position of the high frequency circuit component has been determined, the component-mounting nozzle 20 releases the adsorption, and the high frequency circuit component Mj is provisionally mounted on the adhesive agent 12. The adhesive agent 12 is pressed by the weight of the high frequency circuit component Mj. However, since the weight of the high frequency circuit component Mj is low, the adhesive agent 12 is not broken.

The above operation is repeated, and a necessary number of high frequency circuit components Mj are provisionally mounted on the chassis 1. In the example shown in FIG. 42A, four high frequency circuit components Mj are provisionally mounted on the chassis 1.

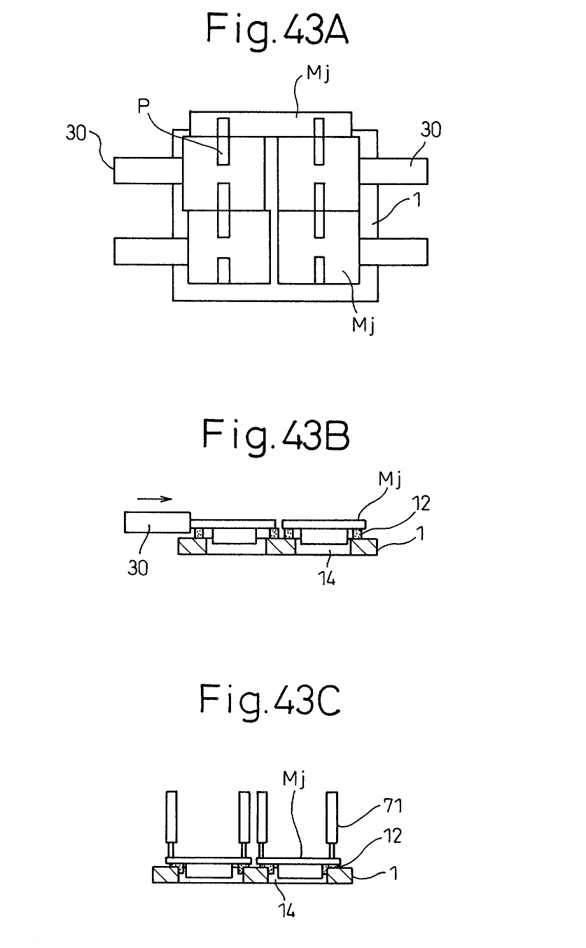

Thereafter, the high frequency circuit components Mj are positioned on the chassis 1 with the actuators 30, as shown in FIG. 43A and FIG. 43B. When the position of a circuit pattern P provided on the upper surface of the high frequency circuit component Mj deviates as shown in FIG. 42B, the actuators 30 operate to match the center position of the circuit pattern P on the chassis 1, as shown in FIG. 43A and FIG. 43B. When the actuators 30 position the high frequency circuit components Mj, it is possible to carry out the positioning by moving the high frequency circuit components Mj while a pattern-positioning apparatus like a micro-camera detects the circuit patterns P on the high frequency circuit components Mj.

When the positions of the high frequency circuit components Mj on the chassis 1 have been determined, the high frequency circuit components Mj are pressed with pressing pins 71 of the pressing mechanism 70, and the high frequency circuit components Mj are adhered onto the chassis 1 with the adhering agent 12, as shown in FIG. 43C. In this example, the high frequency circuit components Mj are individually pressed with the pressing pins 71, and are pressured against the adhesive agent 12 and fixed onto the chassis 1.

To mount the next high frequency circuit component using as a guide a side surface of a high frequency circuit component Mj that has already been mounted, the next high frequency circuit component Mj is brought into contact with the side surface of the high frequency circuit component Mj that has already been mounted. Then, the component-mounting nozzle 20 is returned a constant distance. With this arrangement, it is possible to control the mounting interval between the high frequency circuit components Mj. This control is particularly useful when disposing high frequency circuit components of different systems adjacently.

What is claimed is:

1. A structure of mounting a plurality of high frequency circuit components on a chassis, wherein each of the high frequency circuit components has at least one projection of substantially the same height provided on each of the four side surfaces, and the circuit components are disposed by bringing their projections into contact with adjacent circuit components respectively.

2. A structure of mounting a plurality of high frequency circuit components on a chassis, wherein a heat-resistant film or a heat-resistant tape is adhered to one or both side surfaces of mutually adjacent side surfaces of the high frequency circuit components, thereby to dispose the adjacent circuit components in contact with each other.

3. A structure of mounting a plurality of high frequency circuit components on a chassis, wherein the side surfaces of the high frequency circuit components are brought into contact with each other, and the number of contacted side surfaces is more than one.

4. The structure of mounting high frequency circuit components according to claim 3, wherein the high frequency circuit components are ranked within size tolerance of circuit components, and circuit components of the same rank are used for the mounting.

5. The structure of mounting high frequency circuit components according to claim 4, wherein the high frequency circuit components have their length and width ranked into S, M, and L sizes, respectively, and are classified into a plurality of ranks based on a combination of length and width.

6. A structure of mounting a plurality of high frequency circuit components on a chassis, wherein the high frequency circuit components are divided into a plurality of blocks, each block including a plurality of high frequency circuit components, with the side surfaces of the high frequency circuit components within each block brought into contact with each other.

7. The structure of mounting high frequency circuit components according to claim 6, wherein the blocks are disposed with an interval of an external shape tolerance between adjacent blocks.

8. The structure of mounting high frequency circuit components according to claim 6, wherein the blocks are divided into two systems, one of transmission system blocks, and the other of receiving system blocks.

9. The structure of mounting high frequency circuit components according to claim 6, wherein the blocks are disposed with the distance between the adjacent blocks being substantially zero.

10. The structure of mounting high frequency circuit components according to claim 3 or 6, wherein the circuit components are fixed to the chassis with a conductive adhesive agent.

11. The structure of mounting high frequency circuit components according to claim 3 or 6, wherein end surfaces of the circuit components at which the circuit components are brought into contact with each other have been ground.

12. The structure of mounting high frequency circuit components according to claim 3 or 6, wherein the circuit components are fixed to the chassis with an anisotropic conductive sheet.

13. The structure of mounting high frequency circuit components according to claim 3 or 6, wherein the coefficient of linear expansion of the circuit components is set substantially the same as the coefficient of linear expansion of the chassis.

14. The structure of mounting high frequency circuit components according to claim 3 or 6, wherein the high frequency circuit components are connected to each other with a gold ribbon not having a loop.

15. The structure of mounting high frequency circuit components according to claim 14, wherein the coefficient of linear expansion of the circuit components is set substantially the same as the coefficient of linear expansion of the chassis.

16. The structure of mounting high frequency circuit components according to claim 3 or 6, wherein the high frequency circuit components are connected to each other with solder.

17. The structure of mounting high frequency circuit components according to claim 3 or 6, wherein the high frequency circuit components are connected to each other with a conductive adhesive agent.

18. The structure of mounting high frequency circuit components according to claim 3 or 6, wherein the high frequency circuit components are connected to each other with a metal plate, and the metal plate is connected to the circuit components with an anisotropic conductive sheet.

19. The structure of mounting high frequency circuit components according to claim 3 or 6, wherein the high frequency circuit components are connected to each other with a metal plate, and the metal plate is connected to the circuit components by welding.

20. The structure of mounting high frequency circuit components according to claim 3 or 6, wherein the high frequency circuit components are connected to each other with a gold ribbon, and the gold ribbon is connected to the circuit components with a conductive adhesive agent.

21. The structure of mounting high frequency circuit components according to claim 3 or 6, wherein the high frequency circuit components are connected to each other with a gold ribbon, and the gold ribbon is connected to the circuit components with an anisotropic conductive sheet.

22. The structure of mounting high frequency circuit components on a chassis according to claim 3 or 6, wherein a reference end surface is provided on the chassis, and a reference surface for fixing the high frequency circuit components on the chassis is provided, a base section of a tool having the base section and a claw section is brought into contact with the reference end surface of the chassis, and the circuit components are fixed to the chassis using the end surface of the claw section of the contacted tool as a reference surface.

23. The structure of mounting high frequency circuit components according to claim 3 or 6, wherein a stage is provided on the reference end surface of the chassis, the base section of the tool is brought into contact with a bottom section and a side section of this stage, and the circuit components are fixed to the chassis using the end surface of the claw section of the contacted tool as a reference.

24. The structure of mounting high frequency circuit components according to claim 22, wherein the reference end surface of the chassis is provided in the X axis direction and the Y axis direction of the chassis.

25. The structure of mounting high frequency circuit components according to claim 23, wherein the reference end surface of the chassis is provided in the X axis direction and the Y axis direction of the chassis.

26. The structure of mounting high frequency circuit components according to claim 3 or 6, wherein in fixing the high frequency circuit components onto a chassis, a recess section is provided on the chassis, and the side surface of the corner of the recess section is used as a reference.

27. The structure of mounting high frequency circuit components according to claim 3 or 6, wherein in fixing the high frequency circuit components onto a chassis, a projection is provided on the chassis, and the projection is used as a reference.

28. The structure of mounting high frequency circuit components according to claim 3 or 6, wherein in fixing the high frequency circuit components onto a chassis, a hole is provided in the chassis, and a projection of a tool inserted in the hole is used as a reference.

29. The structure of mounting high frequency circuit components according to claim 3 or 6, wherein in fixing the high frequency circuit components onto a chassis, an antenna connection hole provided in the chassis is used as a reference.

30. A method of mounting a plurality of high frequency circuit components onto a chassis, comprising the steps of: adsorbing each high frequency circuit component with a component-mounting nozzle; conveying each high frequency circuit component onto the chassis or onto a guide fitted to the chassis with the component-mounting nozzle; and bringing at least one of the four side surfaces of the high frequency circuit component into contact with the guide, thereby to position the high frequency circuit components on the chassis.

31. The method of mounting high frequency circuit components according to claim 30, wherein the high frequency circuit components are conveyed using a plurality of component-mounting nozzles the same in number as the components.

32. The method of mounting high frequency circuit components according to claim 31, wherein after sequentially adsorbing the high frequency circuit components with the plurality of component-mounting nozzles, the high frequency circuit components are positioned while the high frequency circuit components are kept adsorbed with the plurality of component-mounting nozzles, and after finishing the positioning of the high frequency circuit components, the high frequency circuit components are collectively conveyed onto the chassis and mounted on the chassis with the plurality of component-mounting nozzles.

33. A method of mounting a plurality of high frequency circuit components onto a chassis, comprising the steps of: adsorbing each high frequency circuit component with a component-mounting nozzle; conveying each high frequency circuit component onto the chassis to provisionally mount the high frequency circuit component on the chassis; and adjusting the position of the high frequency circuit component on the chassis with an actuator disposed around the chassis, thereby to position the high frequency circuit components on the chassis.

34. The method of mounting high frequency circuit components according to claim 33, wherein the plurality of high frequency circuit components are provisionally disposed on a sub-stage in advance, and the plurality of provisionally-disposed high frequency circuit components are collectively conveyed onto the chassis by adsorbing the high frequency circuit components with one or a plurality of component-mounting nozzles.

35. A method of mounting a plurality of high frequency circuit components onto a chassis, comprising the steps of: adsorbing each high frequency circuit component with a component-mounting nozzle; conveying each high frequency circuit component onto a sub-stage with the component-mounting nozzle in advance; adjusting the position of the high frequency circuit component by bringing the high frequency circuit component into contact with a guide provided on the sub-stage; and collectively conveying the plurality of high frequency circuit components after the positional adjustment from the sub-stage onto the chassis by collectively adsorbing the high frequency circuit components with the component-mounting nozzle, thereby to collectively position the high frequency circuit components on the chassis.

36. A method of mounting a plurality of high frequency circuit components onto a chassis, comprising the steps of: adsorbing each high frequency circuit component with a component-mounting nozzle; conveying each high frequency circuit component onto a sub-stage with the component-mounting nozzle in advance; adjusting the position of the high frequency circuit component on the sub-stage with an actuator disposed around the sub-stage; and collectively conveying the plurality of high frequency circuit components after the positional adjustment from the sub-stage onto the chassis by collectively adsorbing the high frequency circuit components with the component-mounting nozzle, thereby to collectively position the high frequency circuit components on the chassis.

37. The method of mounting high frequency circuit components according to claim 35 or 36, wherein the high frequency circuit components are conveyed using a plurality of component-mounting nozzles the same in number as the components.

38. A method of mounting a plurality of high frequency circuit components when a high frequency circuit constructed of the plurality of high frequency circuit components has a plurality of systems, the mounting method comprising the steps of:
provisionally disposing the plurality of high frequency circuit components on a sub-stage for each component that belongs to a system in advance; conveying the plurality of high frequency circuit components provisionally disposed for each system onto the chassis by collectively adsorbing the high frequency circuit components with a component-mounting nozzle; and adjusting the positions of the high frequency circuit components for each system on the chassis, thereby to collectively position the high frequency circuit components on the chassis.

39. The method of mounting high frequency circuit components according to claim 38, wherein the positional adjustment of the high frequency circuit components for each system on the chassis is carried out with a guide that is fitted to the chassis.

40. The method of mounting high frequency circuit components according to claim 38, wherein the positional adjustment of the high frequency circuit components for each system on the chassis is carried out with actuators provided in the vicinity of the chassis.

41. A method of mounting a plurality of high frequency circuit components when a high frequency circuit constructed of the plurality of high frequency circuit components has a plurality of systems, the mounting method comprising the steps of:
adsorbing the plurality of high frequency circuit components for each component that belongs to a system with a component-mounting nozzle; conveying the high frequency circuit components that belong to each system onto a sub-stage with the component-mounting nozzle; positioning the components for each system on the sub-system; collectively adsorbing the positioned components of each system from the sub-system with the component-mounting nozzle; and collectively conveying the high frequency circuit components onto the chassis, thereby to collectively position the high frequency circuit components on the chassis.

42. The method of mounting high frequency circuit components according to claim 41, wherein the positional adjustment of the high frequency circuit components for each system on the sub-stage is carried out with a guide that is fitted to the sub-stage.

43. The method of mounting high frequency circuit components according to claim 41, wherein the positional adjustment of the high frequency circuit components for each system on the sub-stage is carried out with actuators that are provided in the vicinity of the sub-stage.

44. A mounting apparatus for high frequency circuit components that implements the method of claim 30, the mounting apparatus comprising:
a mounting stage on which a chassis is fitted that is mounted with the high frequency circuit components;
a component-mounting nozzle that can adsorb each high frequency circuit component;
a negative pressure supplying unit that supplies negative pressure to the component-mounting nozzle;
a component-mounting nozzle moving unit that moves the component-mounting nozzle from a position where the high frequency circuit components are located to the mounting stage; and
a guide that is fitted on the chassis or in its vicinity, wherein
the component-mounting nozzle adsorbs the high frequency circuit components and conveys the high frequency circuit components onto the chassis that is fitted on the mounting stage, and brings at least one of the four side surfaces of the high frequency circuit components into contact with the guide, thereby to position the high frequency circuit components on the chassis.

45. The mounting apparatus for high frequency circuit components according to claim 44, wherein the number of component-mounting nozzles provided is the same as the number of the high frequency circuit components that are mounted on at least the chassis.

46. The mounting apparatus for high frequency circuit components according to claim 45, wherein the component-mounting nozzle moving unit is provided with a positioning mechanism that enables the plurality of component-mounting nozzles to position the high frequency circuit components while adsorbing the high frequency circuit components.

47. A mounting apparatus for high frequency circuit components that implements the method of claim 33, the mounting apparatus comprising:
a mounting stage on which a chassis is fitted that is mounted with the high frequency circuit components;
a component-mounting nozzle that can adsorb each high frequency circuit component;
a negative pressure supplying unit that supplies negative pressure to the component-mounting nozzle;
a component-mounting nozzle moving unit that moves the component-mounting nozzle from a position where the high frequency circuit components are located to the mounting stage; and
actuators that are disposed around the chassis, wherein
the component-mounting nozzle adsorbs and conveys the high frequency circuit components onto the chassis that is fitted on the mounting stage, and the actuators that are disposed around the chassis adjust the positions of the high frequency circuit components in the chassis, thereby to position the high frequency circuit components on the chassis.

48. The mounting apparatus according to claim 44 or 47, further comprising a sub-stage for provisionally disposing the plurality of high frequency circuit components thereon, wherein the component-mounting nozzle conveys and provisionally disposes the high frequency circuit components on the sub-stage, before conveying the high frequency circuit components onto the chassis on the mounting stage, and the component-mounting nozzle collectively adsorbs the high frequency circuit components after they have been provisionally disposed, and conveys the high frequency circuit components onto the chassis.

49. A mounting apparatus for high frequency circuit components that implements the method of claim 35, the mounting apparatus comprising:
a mounting stage on which a chassis is fitted that is mounted with the high frequency circuit components;
a component-mounting nozzle that can adsorb each high frequency circuit component;
a negative pressure supplying unit that supplies negative pressure to the component-mounting nozzle;
a sub-stage on which the high frequency circuit component are provisionally disposed;
a component-mounting nozzle moving unit that moves the component-mounting nozzle from a position where the high frequency circuit components are located to the sub-stage and the mounting stage; and
a positioning guide for the high frequency circuit components that is disposed on the sub-stage, wherein
the component-mounting nozzle adsorbs the high frequency circuit components and adjusts the positions of the high frequency circuit components on the sub-stage, and collectively conveys the position-adjusted high frequency circuit components onto the chassis that is fitted on the mounting stage, thereby to position the high frequency circuit components on the chassis.

50. A mounting apparatus for high frequency circuit components that implements the method of claim 36, the mounting apparatus comprising:
a mounting stage on which a chassis is fitted that is mounted with the high frequency circuit components;
a component-mounting nozzle that can adsorb each high frequency circuit component;
a negative pressure supplying unit that supplies negative pressure to the component-mounting nozzle;
a sub-stage on which the high frequency circuit component are provisionally disposed;
a component-mounting nozzle moving unit that moves the component-mounting nozzle from a position where the high frequency circuit components are located to the sub-stage and the mounting stage; and
positioning actuators for the high frequency circuit components that are disposed on around the sub-stage, wherein
the component-mounting nozzle adsorbs the high frequency circuit components and adjusts the positions of the high frequency circuit components on the sub-stage, and collectively conveys the position-adjusted high frequency circuit components onto the chassis that is fitted on the mounting stage, thereby to position the high frequency circuit components on the chassis.

51. The mounting apparatus according to any one of claims 44, 47, and 49, wherein the number of component-mounting nozzles provided is the same as the number of the plurality of high frequency circuit components that are disposed on the chassis, or the same as the number of circuit components that belong to one system on the chassis.

52. The mounting apparatus according to any one of claims 44, 47, and 49, further comprising an X-Y table that moves the mounting stage in the X and Y directions, wherein the X-Y table can move the mounting stage to outside the movable range of the component-mounting nozzle moving unit.

53. The mounting apparatus according to claim 52, wherein a pattern-positioning apparatus for the high frequency circuit components provisionally disposed on the chassis is provided within the movable range of the mounting stage based on the X-Y table, and the positions of the high frequency circuit components are fine-adjusted on the chassis or with the actuators provided in its vicinity at the position of the pattern-positioning apparatus.

54. The mounting apparatus according to any one of claims 44, 47, and 49, further comprising pressing pins that press the high frequency circuit components against the chassis in a pressing stage, wherein the pressing pins individually press high frequency circuit components positioning of which has been completed on the chassis, and the high frequency circuit components are fixed onto the chassis by pressing the high frequency circuit components against an adhesive agent that has been coated on the chassis.
